(19) United States
(12) Patent Application Publication
(10) Pub. No.: US 2026/0076248 A1
(43) Pub. Date: Mar. 12, 2026

(54) BONDED STRUCTURE, SEMICONDUCTOR DEVICE, AND BONDING METHOD

(71) Applicant: Rohm Co., Ltd., Kyoto-shi (JP)

(72) Inventor: Oji SATO, Kyoto-shi (JP)

(21) Appl. No.: 19/386,866

(22) Filed: Nov. 12, 2025

Related U.S. Application Data
(63) Continuation of application No. PCT/JP2024/015532, filed on Apr. 19, 2024.

(30) Foreign Application Priority Data
May 19, 2023 (JP) 2023-083268

(51) Int. Cl. H01L 23/00

(52) U.S. Cl. CPC H10W 72/30; H10W 72/073; H10W 72/07331; H10W 72/352; H10W 72/952; H10W 90/734

(57) ABSTRACT

A bonding structure includes a first member and a second member. The first member includes a first layer mainly composed of a first metal. The second member includes a second layer mainly composed of a second metal different from the first metal. In the bonding structure, the first layer of the first member and the second layer of the second member are solid-phase bonded. As an example, the first metal is Cu, and the second metal is Ag. As another example, the first metal is Cu, and the second metal is Au. As a still another example, the first metal is Au, and the second metal is Ag.

### TECHNICAL FIELD

The present disclosure relates to a bonding structure, a semiconductor device, and a bonding method.

### BACKGROUND ART

Various configurations have been proposed for a semiconductor device incorporating a semiconductor element. WO2020/085377 discloses an example of a conventional semiconductor device. The semiconductor device disclosed in WO2020/085377 includes a semiconductor element, a conductive member, a support member, and a sealing resin. The semiconductor element is bonded to the obverse surface of the conductive member. A second metal layer containing Ag (silver) is disposed on the reverse surface of the conductive member. A first metal layer containing Ag (silver) is disposed on the support surface of the support member. The conductive member and the support member are bonded together by solid-phase diffusion bonding of the first metal layer and the second metal layer.

### BRIEF DESCRIPTION OF THE DRAWINGS

FIG. 1 is a perspective view of a semiconductor device according to a first embodiment of the present disclosure.

FIG. 2 is a perspective view corresponding to FIG. 1, from which the sealing resin is omitted.

FIG. 3 is a perspective view corresponding to FIG. 2, from which the first conductive member is omitted.

FIG. 4 is a plan view of the semiconductor device according to the first embodiment of the present disclosure.

FIG. 5 is a plan view corresponding to FIG. 4, from which the sealing resin is omitted.

FIG. 6 is a partially enlarged view in which a portion of FIG. 5 is enlarged and the sealing resin is omitted.

FIG. 7 is a plan view corresponding to FIG. 5 in which the sealing resin and the first conductive member are omitted and the second conductive member is indicated by imaginary lines.

FIG. 8 is a bottom view of the semiconductor device according to the first embodiment of the present disclosure.

FIG. 9 is a sectional view taken along line IX-IX in FIG. 5.

FIG. 10 is a sectional view taken along line X-X in FIG. 5.

FIG. 11 is a partially enlarged view in which a portion of FIG. 10 is enlarged.

FIG. 12 is a partially enlarged view in which a portion of FIG. 10 is enlarged.

FIG. 13 is a sectional view taken along line XIII-XIII in FIG. 5.

FIG. 14 is a sectional view taken along line XIV-XIV in FIG. 5.

FIG. 15 is a sectional view taken along line XV-XV in FIG. 5.

FIG. 16 is a schematic front view for describing the bonding structure of the semiconductor device according to the first embodiment of the present disclosure, in which the sealing resin and the like are omitted.

FIG. 17 is an image of the bonding area between a bonding member and a support substrate taken using a scanning electron microscope.

FIG. 18 is a schematic front view showing a step of a method for manufacturing the semiconductor device according to the first embodiment of the present disclosure.

FIG. 19 is a sectional view showing an example of a semiconductor device assembly incorporating the semiconductor device according to the first embodiment of the present disclosure.

FIG. 20 is a schematic view of a vehicle in which the semiconductor device according to the first embodiment of the present disclosure is mounted.

FIG. 21 is a sectional view of a semiconductor device according to a second embodiment of the present disclosure.

FIG. 22 is a schematic front view for describing the bonding structure of the semiconductor device according to the second embodiment of the present disclosure.

### DETAILED DESCRIPTION OF EMBODIMENTS

The following describes preferred embodiments of the present disclosure in detail with reference to the drawings.

In the present disclosure, the terms such as “first”, “second”, and “third” are used merely as labels and are not intended to impose ordinal requirements on the items to which these terms refer.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”. Furthermore, in the description of the present disclosure, the expression “A surface A faces (a first side or a second side) in a direction B” is not limited to the situation where the angle of the surface A to the direction B is 90°and includes the situation where the surface A is inclined with respect to the direction B.

### First Embodiment

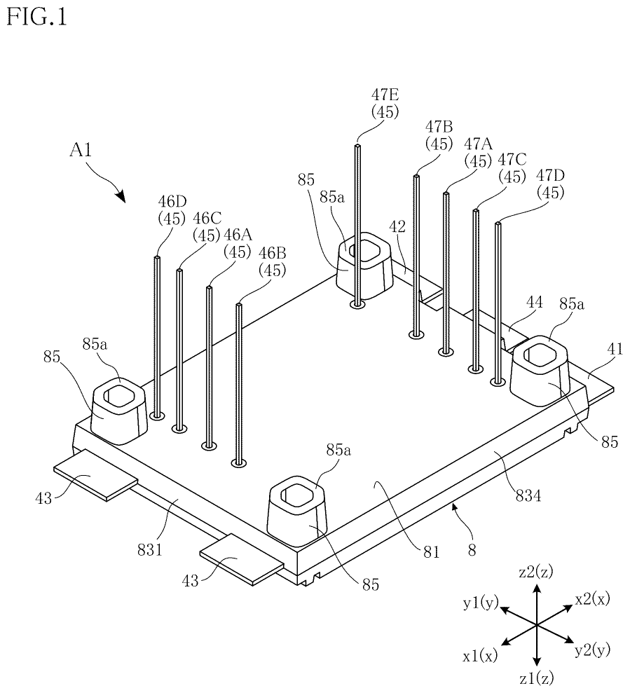

FIGS. 1 to 16 show a semiconductor device according to a first embodiment of the present disclosure. The semiconductor device A1 of the present embodiment includes a plurality of first semiconductor elements 10A, a plurality of second semiconductor elements 10B, a conductive substrate 2, a support substrate 3, bonding members 19 and 29, a first terminal 41, a second terminal 42, a plurality of third terminals 43, a fourth terminal 44, a plurality of control terminals 45, a control terminal support 48, a first conductive member 5, a second conductive member 6, and a sealing resin 8.

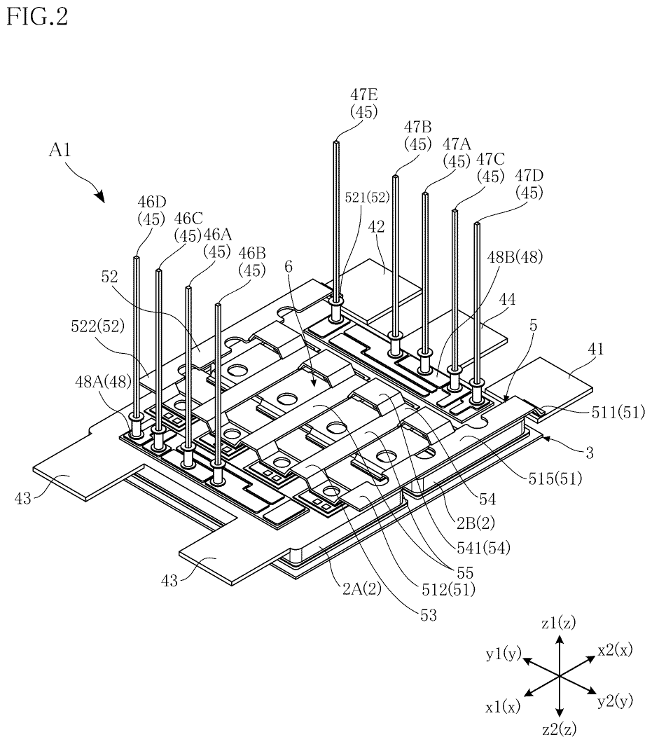

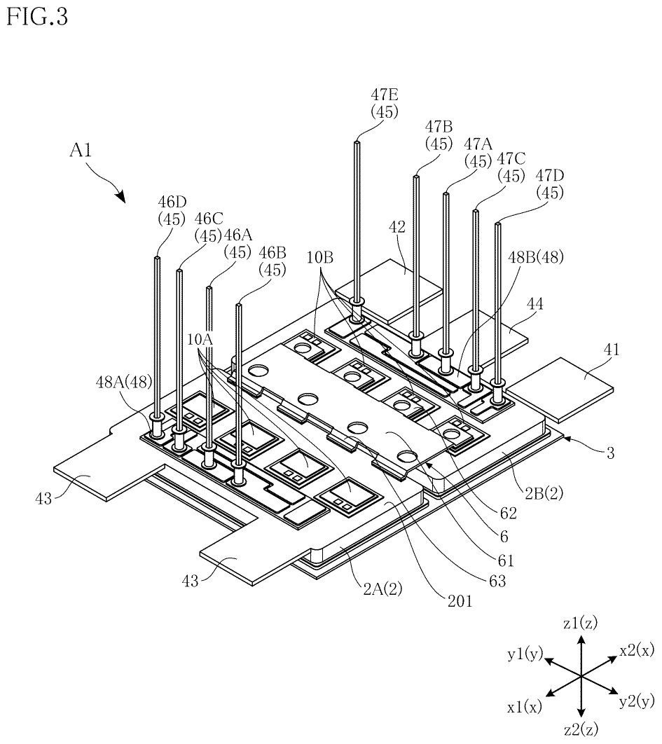

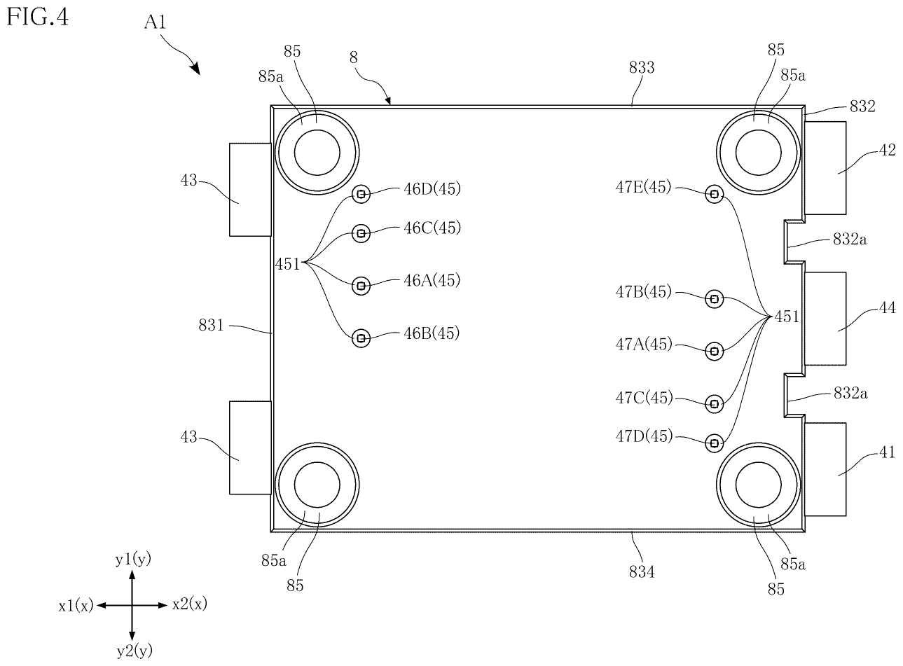

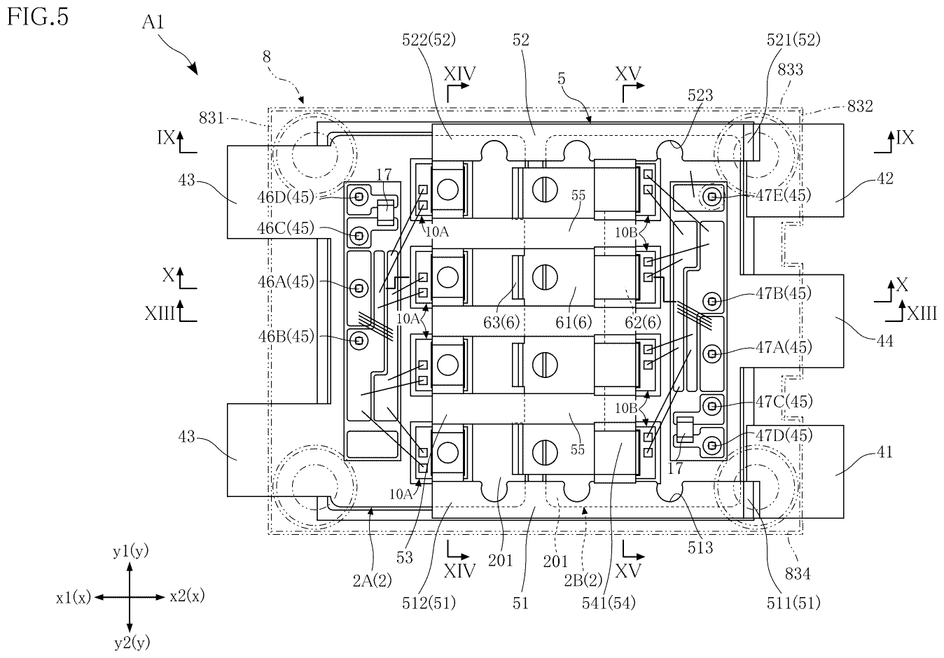

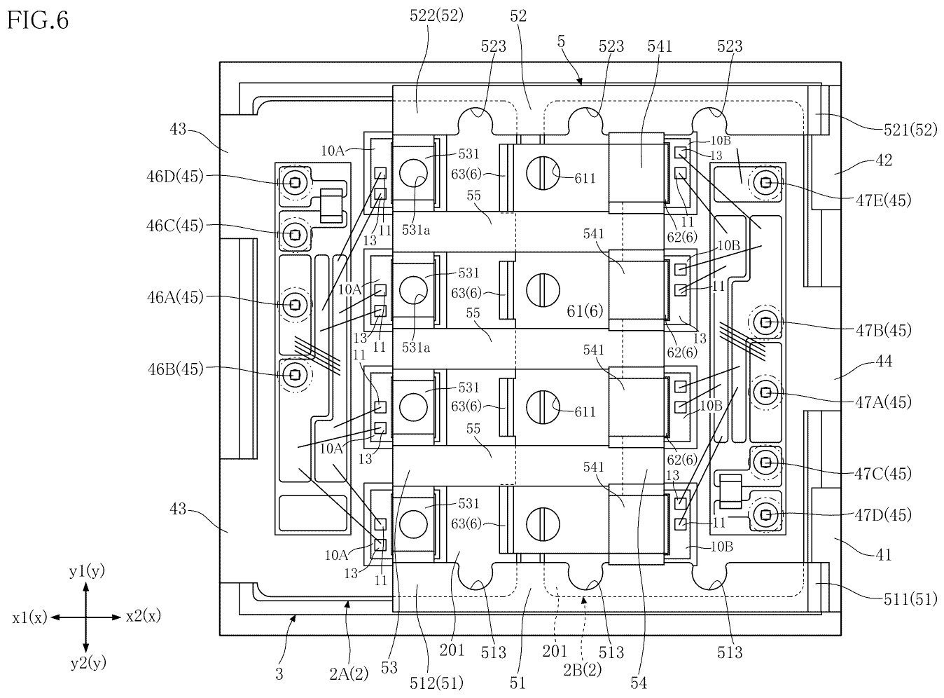

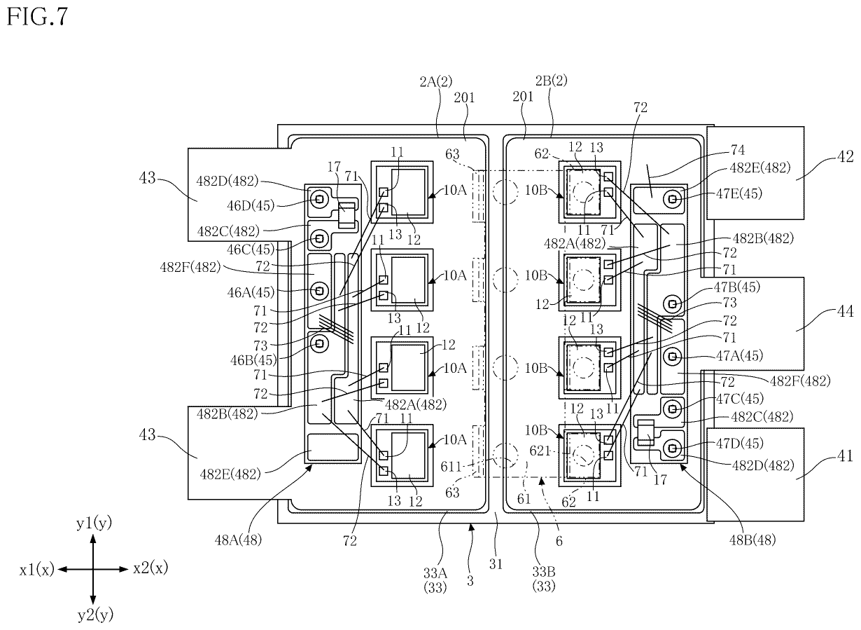

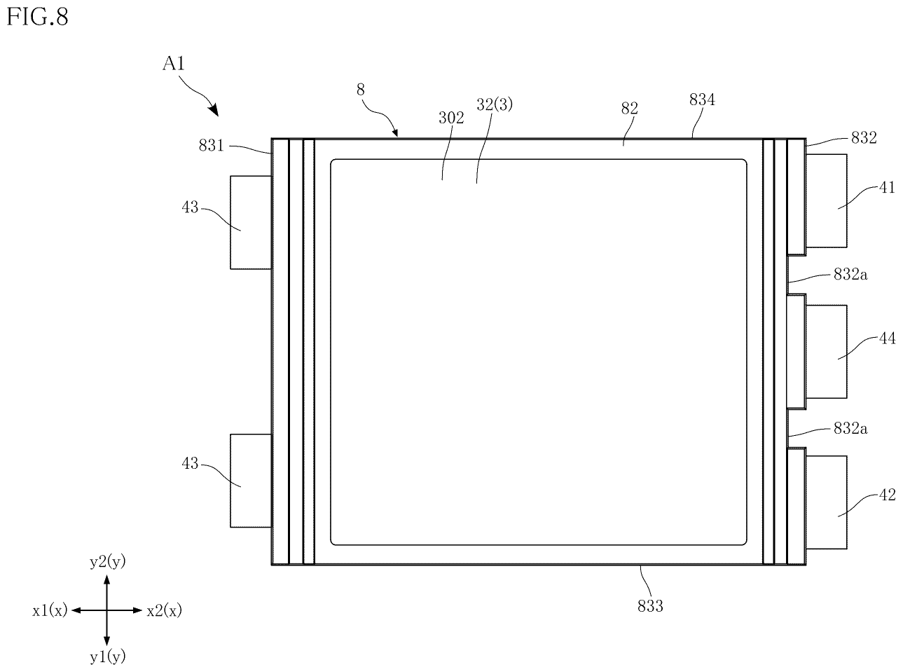

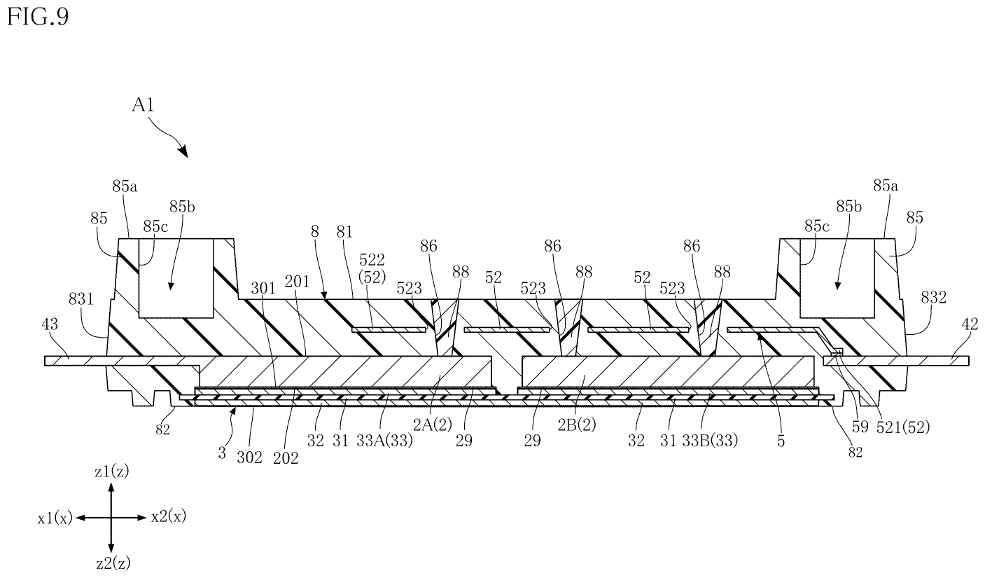

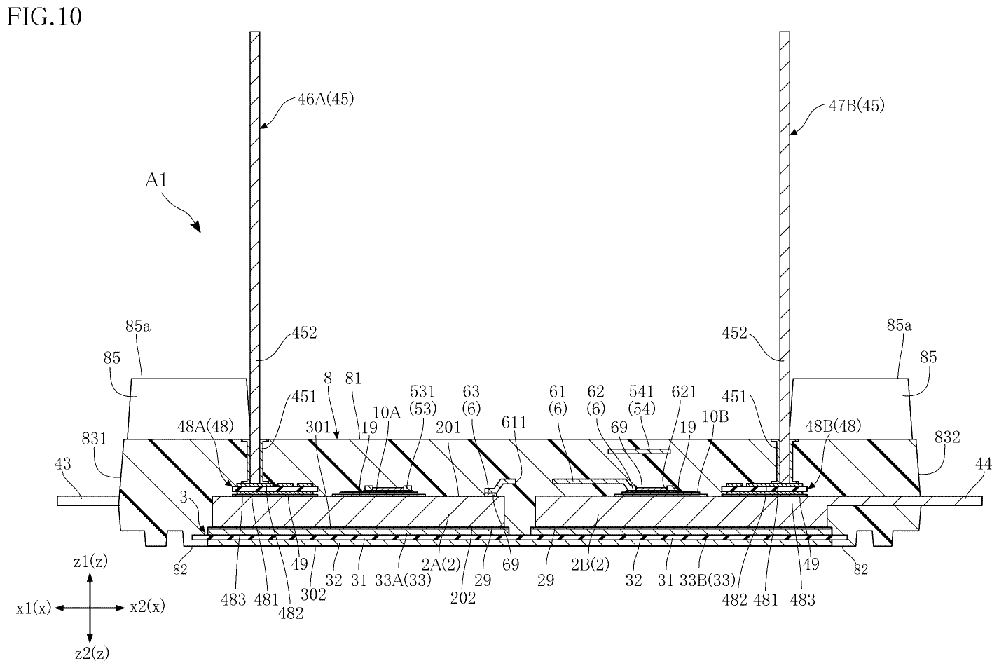

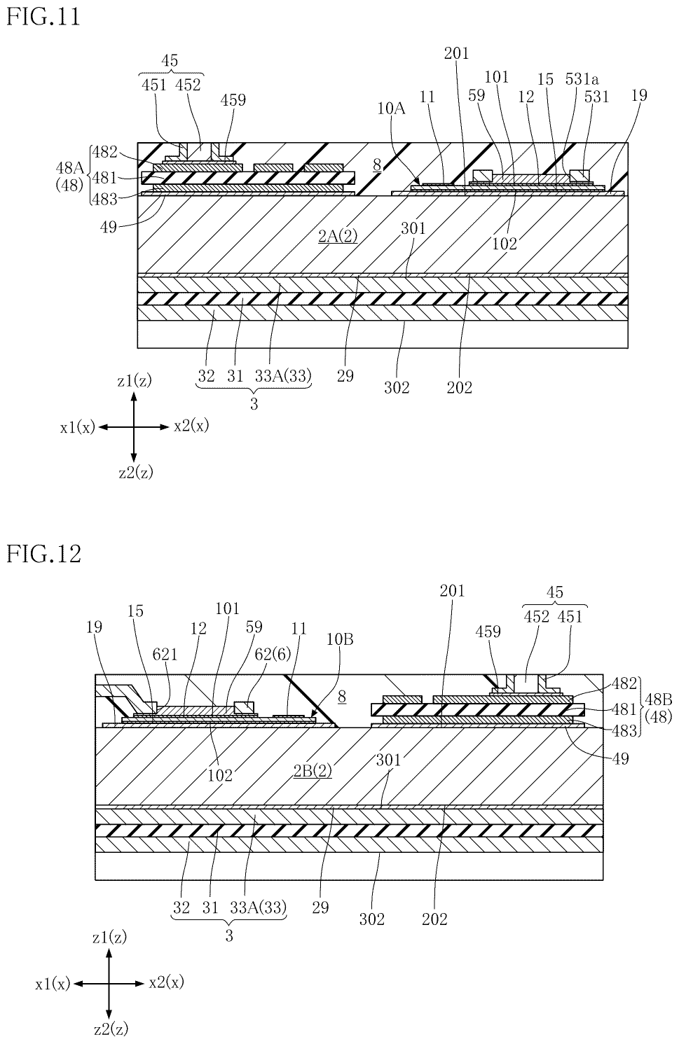

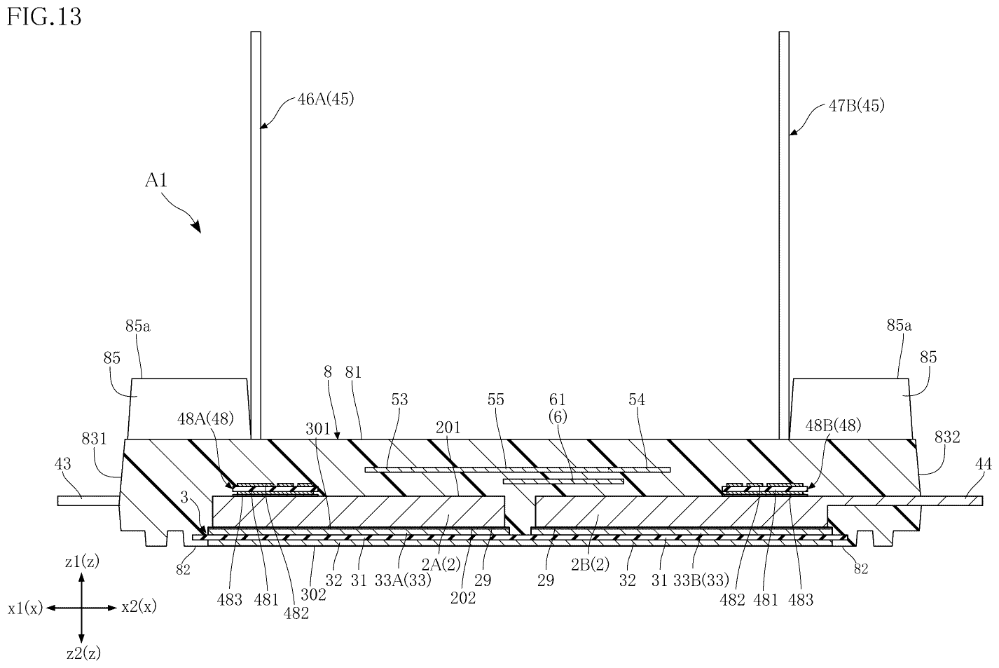

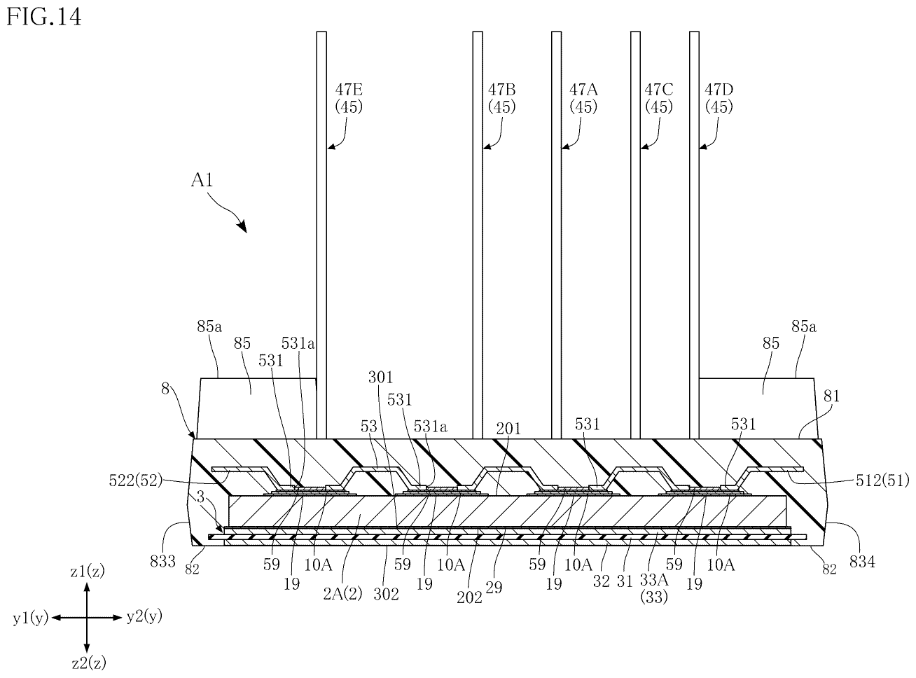

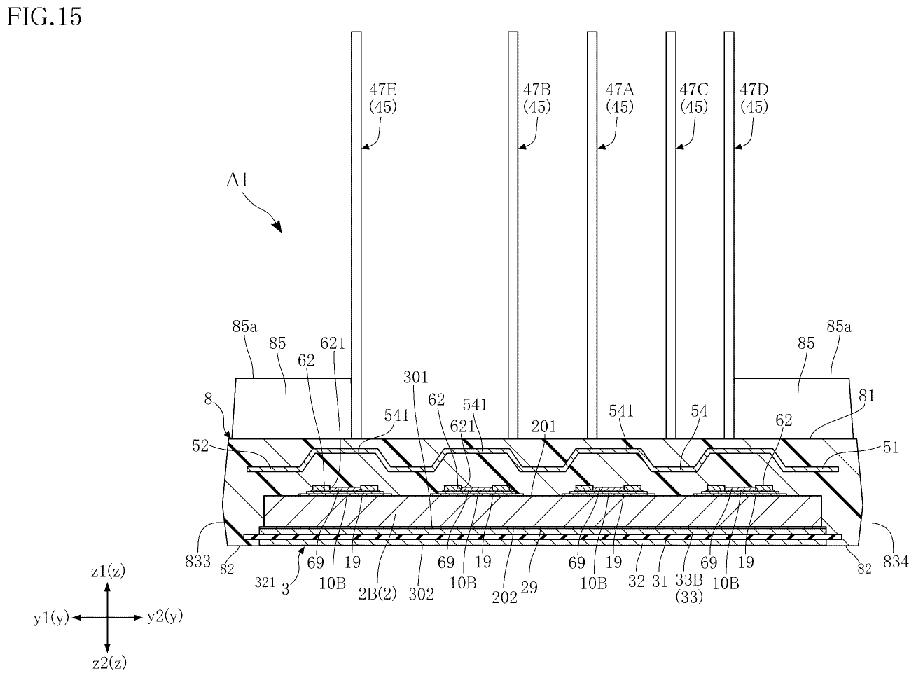

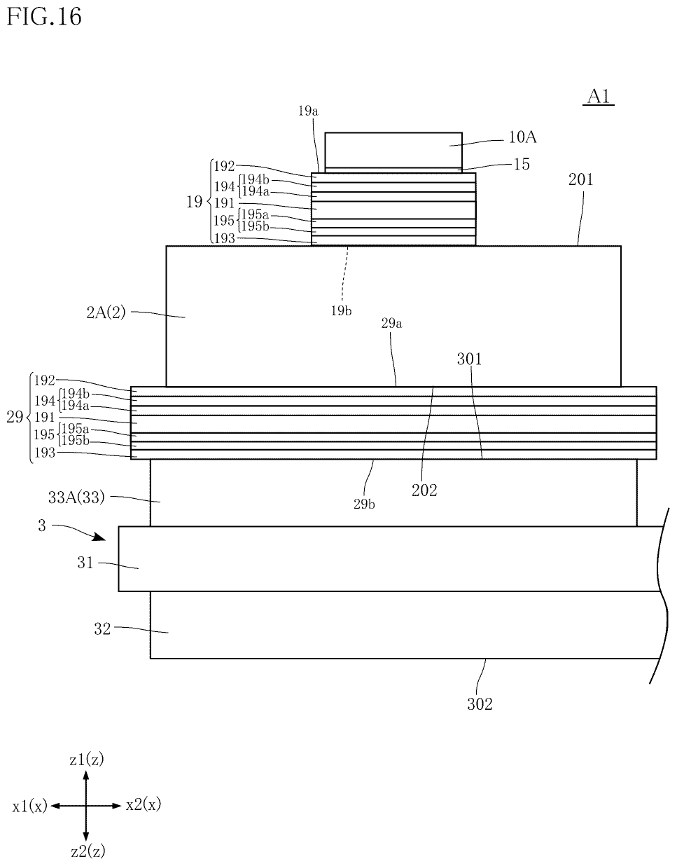

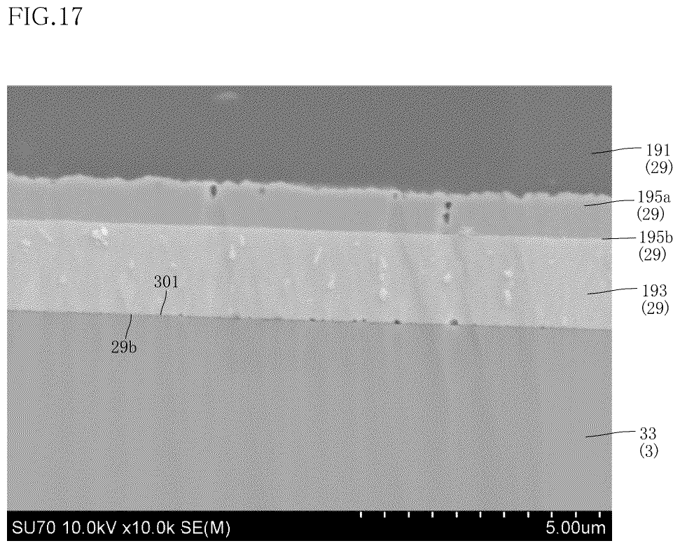

FIG. 1 is a perspective view of a semiconductor device A1. FIG. 2 is a perspective view corresponding to FIG. 1, from which the sealing resin 8 is omitted. FIG. 3 is a perspective view corresponding to FIG. 2, from which the first conductive member 5 is omitted. FIG. 4 is a plan view of the semiconductor device A1. FIG. 5 is a plan view corresponding to FIG. 4, in which the sealing resin 8 is indicated by imaginary lines. FIG. 6 is a partially enlarged view in which a portion of FIG. 5 is enlarged and the sealing resin 8 is omitted. FIG. 7 is a plan view corresponding to FIG. 5 from which the sealing resin 8 and the first conductive member 5 are omitted and in which the second conductive member 6 is indicated by imaginary lines. FIG. 8 is a bottom view of the semiconductor device A1. FIG. 9 is a sectional view taken along line IX-IX in FIG. 5. FIG. 10 is a sectional view taken along line X-X in FIG. 5. FIGS. 11 and 12 are partially enlarged views in which a portion of FIG. 10 is enlarged. FIG. 13 is a sectional view taken along line XIII-XIII in FIG. 5. FIG. 14 is a sectional view taken along line XIV-XIV in FIG. 5. FIG. 15 is a sectional view taken along line XV-XV in FIG. 5. FIG. 16 is a schematic front view for describing the bonding structure of the semiconductor device shown in FIGS. 1 to 15, in which the sealing resin 8 and the like are omitted.

In these figures, the thickness direction of the semiconductor device A1 is referred to as the “thickness direction z”. A direction orthogonal to the thickness direction z is referred to as the “first direction x”. The direction orthogonal to the thickness direction z and the first direction x is referred to as the “second direction y”. In the description below, “in plan view” means as viewed in the thickness direction z. The z1 side in the thickness direction z may be referred to as “upper”, and the z2 side in the thickness direction z may be referred to as “lower”.

Each of the first semiconductor elements 10A and the second semiconductor elements 10B is an electronic component as a core for the function of the semiconductor device A1, and an example of the “semiconductor element” of the present disclosure. The constituent material of the first semiconductor elements 10A and the second semiconductor elements 10B is, for example, a semiconductor material mainly composed of SiC (silicon carbide). The semiconductor material is not limited to SiC and may be Si (silicon), GaN (gallium nitride) or C (diamond), for example. Each of the first semiconductor elements 10A and the second semiconductor elements 10B is a power semiconductor chip having a switching function, such as a MOSFET (Metal Oxide Semiconductor Field Effect Transistor). The first semiconductor elements 10A and the second semiconductor elements 10B are MOSFETs in the present embodiment, but are not limited to these and may be other transistors such as IGBTs (Insulated Gate Bipolar Transistors). The first semiconductor elements 10A and the second semiconductor elements 10B are all identical with each other. Each of the first semiconductor elements 10A and the second semiconductor elements 10B is, for example, an n-channel MOSFET, but may be a p-channel MOSFET.

As shown in FIGS. 11 and 12, each of the first semiconductor elements 10A and the second semiconductor elements 10B has an element obverse surface 101 and an element reverse surface 102. In each of the first semiconductor elements 10A and the second semiconductor elements 10B, the element obverse surface 101 and the element reverse surface 102 are spaced apart from each other in the thickness direction z. The element obverse surface 101 faces the z1 side in the thickness direction z, and the element reverse surface 102 faces the z2 side in the thickness direction z.

In the present embodiment, the semiconductor device A1 includes four first semiconductor elements 10A and four second semiconductor elements 10B. The number of first semiconductor elements 10A and the number of second semiconductor elements 10B are not limited to this, and may be changed as appropriate in accordance with the performance required of the semiconductor device A1. In the example shown in FIG. 7, four each of the first semiconductor elements 10A and the second semiconductor elements 10B are provided. The number of first semiconductor elements 10A and the number of second semiconductor elements 10B may be two, three, or five or more. The number of first semiconductor elements 10A and the number of second semiconductor elements 10B may be the same or may be different. The number of first semiconductor elements 10A and the number of second semiconductor elements 10B are determined based on the current capacity of the semiconductor device A1.

The semiconductor device A1 may be configured as a half-bridge type switching circuit. In this case, in the semiconductor device A1, the second semiconductor elements 10B form the upper arm circuit, and the first semiconductor elements 10A form the lower arm circuit. In the upper arm circuit, the second semiconductor elements 10B are connected in parallel with each other. In the lower arm circuit, the first semiconductor elements 10A are connected in parallel with each other. Each second semiconductor element 10B and a relevant one of the first semiconductor elements 10A are connected in series to form a bridge layer.

As shown in FIGS. 7 and 14 in particular, each of the first semiconductor elements 10A is mounted on the conductive substrate 2. In the example shown in FIG. 7, the first semiconductor elements 10A may be aligned in the second direction y and are spaced apart from each other. Each of the first semiconductor elements 10A is conductively bonded to the conductive substrate 2 (the first conductive portion 2A, described later) via a bonding member 19. When the first semiconductor elements 10A are bonded to the first conductive portion 2A, the element reverse surfaces 102 face the first conductive portion 2A.

As shown in FIGS. 7 and 15 in particular, each of the second semiconductor elements 10B is mounted on the conductive substrate 2. In the example shown in FIG. 7, the second semiconductor elements 10B may be aligned in the second direction y and are spaced apart from each other. Each of the second semiconductor elements 10B is conductively bonded to the conductive substrate 2 (the second conductive portion 2B, described later) via a bonding member 19. When the second semiconductor elements 10B are bonded to the second conductive portion 2B, the element reverse surfaces 102 face the second conductive portion 2B. As understood from FIG. 7, the first semiconductor elements 10A and the second semiconductor elements 10B overlap with each other as viewed in the first direction x, but these may not overlap with each other.

Each of the first semiconductor elements 10A and the second semiconductor elements 10B has a first obverse surface electrode 11, a second obverse surface electrode 12, a third obverse surface electrode 13, and a reverse surface electrode 15. The configurations of the first obverse surface electrode 11, the second obverse surface electrode 12, the third obverse surface electrode 13 and the reverse surface electrode 15 described below are common to the first semiconductor elements 10A and the second semiconductor elements 10B. The first obverse surface electrode 11, the second obverse surface electrode 12, and the third obverse surface electrode 13 are provided on the element obverse surface 101. The first obverse surface electrode 11, the second obverse surface electrode 12, and the third obverse surface electrode 13 are insulated from each other by an insulating film, not shown. The reverse surface electrode 15 is provided on the element reverse surface 102.

The first obverse surface electrode 11 is, for example, a gate electrode, through which a drive signal (e.g., gate voltage) for driving the first semiconductor element 10A (the second semiconductor element 10B) is inputted. In each first semiconductor element 10A (each second semiconductor element 10B), the second obverse surface electrode 12 is, for example, a source electrode, through which a source current flows. The third obverse surface electrode 13 is, for example, a source sense electrode, through which a source current flows. The reverse surface electrode 15 is, for example, a drain electrode, through which a drain current flows. The reverse surface electrode 15 covers the entire (or almost entire) element reverse surface 102. The reverse surface electrode 15 is formed by Ag (silver) sputtering. The reverse surface electrode 15 may be formed by Au (gold) sputtering.

Each of the first semiconductor elements 10A (the second semiconductor elements 10B) switches between a conducting state and a disconnected state in response to a drive signal (gate voltage) inputted to the first obverse surface electrode 11 (the gate electrode). In the conducting state, a current flows from the reverse surface electrode 15 (the drain electrode) to the second obverse surface electrode 12 (the source electrode). In the disconnected state, this current does not flow. That is, each first semiconductor element 10A (each second semiconductor element 10B) performs a switching operation. The semiconductor device A1 uses the switching function of the first semiconductor elements 10A and the second semiconductor elements 10B to convert the DC voltage inputted between the single fourth terminal 44 and the two, i.e., the first and the second terminals 41 and 42 into e.g. AC voltage and outputs the AC voltage from the third terminal 43.

As shown in FIG. 5 and 10 in particular, the semiconductor device A1 includes thermistors 17. The thermistors 17 are used as a temperature detection sensor.

The conductive substrate 2 supports the first semiconductor elements 10A and the second semiconductor elements 10B. The conductive substrate 2 is bonded on the support substrate 3 via the bonding members 29. The constituent material of the conductive substrate 2 is mainly composed of Cu (copper), for example. The phrase “is mainly composed of” includes the case where components other than the mentioned main component are not contained. Thus, the constituent material of the conductive substrate 2 may be Cu that does not contain other elements, or may be a Cu alloy. The constituent material of the conductive substrate 2 is not limited, and may be mainly composed of other metals. The conductive substrate 2 includes a first conductive portion 2A and a second conductive portion 2B. Each of the first conductive portion 2A and the second conductive portion 2B is a plate that is rectangular in plan view. The first conductive portion 2A and the second conductive portion 2B, together with the first terminal 41, the second terminal 42, the third terminals 43, the fourth terminal 44, the first conductive member 5 and the second conductive member 6 form a conduction path of a main circuit current to the first semiconductor elements 10A and the second semiconductor elements 10B. As shown in FIGS. 9 to 15, each of the first conductive portion 2A and the second conductive portion 2B is bonded on the support substrate 3 via a bonding member 29. Each of the first semiconductor elements 10A is bonded to the first conductive portion 2A via a bonding member 19. Each of the second semiconductor elements 10B is bonded to the second conductive portion 2B via a bonding member 19. As shown in FIGS. 3, 7, 9 and 10, the first conductive portion 2A and the second conductive portion 2B are spaced apart from each other in the first direction x. In the example shown in these figures, the first conductive portion 2A is located on the x1 side in the first direction x from the second conductive portion 2B. The first conductive portion 2A and the second conductive portion 2B overlap with each other as viewed in the first direction x. Each of the first conductive portion 2A and the second conductive portion 2B has dimensions of, for example, 15 mm to 25 mm in the first direction x, 30 mm to 40 mm in the second direction y, and 1.0 mm to 5.0 mm (preferably, about 2.0 mm) in the thickness direction z.

The conductive substrate 2 has an obverse surface 201 and a reverse surface 202. As shown in FIGS. 9, 10, 13 to 15, and 16, the obverse surface 201 and the reverse surface 202 are spaced apart from each other in the thickness direction z. The obverse surface 201 faces the z1 side in the thickness direction z, and the reverse surface 202 faces the z2 side in the thickness direction z. The obverse surface 201 is constituted of the upper surface of the first conductive portion 2A and the upper surface of the second conductive portion 2B. The fist semiconductor elements 10A and the second semiconductor elements 10B are bonded to the obverse surface 201 via the bonding members 19. The reverse surface 202 is constituted of the lower surface of the first conductive portion 2A and the lower surface of the second conductive portion 2B. The reverse surface 202 is conductively bonded to the support substrate 3 via the bonding members 29 such that it faces the support substrate 3. The obverse surface 201 and the reverse surface 202 of the conductive substrate 2 are not provided with a metal layer such as Ag (silver) plating.

The support substrate 3 supports the conductive substrate 2. The support substrate 3 may be provided by an AMB (Active Metal Brazing) substrate. The support substrate 3 includes an insulating layer 31, a first metal layer 32, and a second metal layer 33.

The insulating layer 31 may be a ceramic material having excellent thermal conductivity, for example. Examples of such a ceramic material include SiN (silicon nitride). The insulating layer 31 is not limited to a ceramic material and may be a sheet of insulating resin, for example. The insulating layer 31 is, for example, rectangular in plan view.

The second metal layer 33 is formed on the upper surface (the surface facing the z1 side in the thickness direction z) of the insulating layer 31. The constituent material of the second metal layer 33 is mainly composed of, for example, Cu (copper), and may be Cur or a Cu alloy. The constituent material of the second metal layer 33 is not limited, may be mainly composed of other metals such as Al (aluminum). The second metal layer 33 includes a first portion 33A and a second portion 33B. The first portion 33A and the second portion 33B are spaced apart from each other in the first direction x. The first portion 33A is located on the x1 side in the first direction x from the second portion 33B. The first conductive portion 2A is conductively bonded to the first portion 33A via a bonding member 29 and supported by the first portion 33A. The second conductive portion 2B is conductively bonded to the second portion 33B via a bonding member 29 and supported by the second portion 33B. Each of the first portion 33A and the second portion 32B is, for example, rectangular in plan view.

The first metal layer 32 is formed on the lower surface (the surface facing the z2 side in the thickness direction z) of the insulating layer 31. The constituent material of the first metal layer 32 is the same as that of the second metal layer 33. As shown in FIG. 8, the lower surface (the bottom surface 302, described later) of the first metal layer 32 is exposed from the sealing resin 8. The first metal layer 32 overlaps with both the first portion 33A and the second portion 33B in plan view. As shown in FIGS. 9 to 15 and 16, the support substrate 3 has a support surface 301 and a bottom surface 302. The support surface 301 and the bottom surface 302 are spaced apart from each other in the thickness direction z. The support surface 301 faces the z1 side in the thickness direction z, and the bottom surface 302 faces the z2 side in the thickness direction z. As shown in FIG. 8, the bottom surface 302 is exposed from the sealing resin 8. More specifically, the second metal layer 33 has the support surface 301, and the first metal layer 32 has the bottom surface 302. The support surface 301 is the upper surface of the second metal layer 33 and constituted of the upper surface of the first portion 33A and the upper surface of the second portion 33B. The support surface 301 faces the conductive substrate 2, and the conductive substrate 2 is conductively bonded to the support surface 301 via the bonding member 29. The bottom surface 302 is the lower surface of the first metal layer 32. A heat dissipation member such as a heat sink, not shown, can be attached to the bottom surface 302. The support surface 301 and the bottom surface 302 of the support substrate 3 are not provided with a metal layer such as Ag (silver) plating. The dimension of the support substrate 3 in the thickness direction z (the distance from the support surface 301 to the bottom surface 302 along the thickness direction z) is, for example, 0.7 mm to 2.0 mm.

The bonding member 19 is interposed between a semiconductor element 10A (a second semiconductor element 10B) and the first conductive portion 2A (the second conductive portion 2B) of the conductive substrate 2 to conductively bond the first semiconductor element 10A (the second semiconductor element 10B) and the first conductive portion 2A (the second conductive portion 2B). The bonding member 19 and the first semiconductor element 10A (the second semiconductor element 10B) are solid-phase bonded, and the bonding member 19 and the first conductive portion 2A (the second conductive portion 2B) are solid-phase bonded. The bonding member 29 is interposed between the first conductive portion 2A (the second conductive portion 2B) of the first conductive substrate 2 and the first portion 33A (the second portion 33B) of the second metal layer 33 of the support substrate 3 to conductively bond the first conductive portion 2A (the second conductive portion 2B) and the first portion 33A (the second portion 33B). The bonding member 29 and the first conductive portion 2A (the second conductive portion 2B) are solid-phase bonded, and the bonding member 29 and the first portion 33A (the second conductive portion 33B) are solid-phase bonded. In the present embodiment, the bonding member 19 and the bonding member 29 are metal foils with a thickness dimension (the dimension in the thickness direction z) of about 100 μm.

As shown in FIG. 17, the bonding member 19 and the bonding member 29 each include a body layer 191, an obverse layer 192, a reverse layer 193, and intermediate layers 194 and 195. The body layer 191 is the main part of the bonding member 19, 29, and the constituent material is, for example, Al (aluminum) or an Al alloy. The intermediate layer 194 is disposed in contact with the surface of the body layer 191 that faces the z1 side in the thickness direction z. The intermediate layer 194 includes an Ni layer 194a in contact with the body layer 191, and a Cu layer 194b in contact with the Ni layer 194a. The obverse layer 192 is disposed in contact with the surface of the intermediate layer 194 that faces the z1 side in the thickness direction z, and is located furthest to the z1 side of the bonding member 19, 29. The constituent material of the obverse layer 192 is Ag. The intermediate layer 195 is disposed in contact with the surface of the body layer 191 that faces the z2 side in the thickness direction z. The intermediate layer 195 includes an Ni layer 195a in contact with the body layer 191, and a Cu layer 195b in contact with the Ni layer 195a. The reverse layer 193 is disposed in contact with the surface of the intermediate layer 195 that faces the z2 side in the thickness direction z, and is located furthest to the z2 side of the bonding member 19, 29. The constituent material of the reverse layer 193 is Ag. Thus, the obverse layer 192 and the reverse layer 193, which are made of Ag, are disposed on opposite ends in the thickness direction z of the bonding member 19, 29. The intermediate layers 194 and 195 are formed by plating the body layer 191, for example. The obverse layer 192 is formed by plating the intermediate layer 194, for example. The reverse layer 193 is formed by plating the intermediate layer 195, for example. The method for forming the bonding member 19, 29 is not limited. The constituent materials of the body layer 191, the obverse layer 192, the reverse layer 193, and the intermediate layers 194 and 195 are not limited. For example, the constituent material of the obverse layer 192 and the reverse layer 193 may be an alloy containing Ag or mainly composed of Au.

The bonding member 19 has an obverse surface 19a and a reverse surface 19b. As shown in FIG. 16, the obverse surface 19a and the reverse surface 19b are spaced apart from each other in the thickness direction z. The obverse surface 19a faces the z1 side in the thickness direction z, and the reverse surface 19b faces the z2 side in the thickness direction z. The obverse surface 19a is the surface of the obverse layer 192 that faces the z1 side in the thickness direction z, and faces the first semiconductor element 10A (the second semiconductor element 10B). The reverse surface 19b is the surface of the reverse layer 193 that faces the z2 side in the thickness direction z, and faces the conductive substrate 2. The bonding member 29 has an obverse surface 29a and a reverse surface 29b. As shown in FIG. 16, the obverse surface 29a and the reverse surface 29b are spaced apart from each other in the thickness direction z. The obverse surface 29a faces the z1 side in the thickness direction z, and the reverse surface 29b faces the z2 side in the thickness direction z. The obverse surface 29a is the surface of the obverse layer 192 that faces the z1 side in the thickness direction z, and faces the conductive substrate 2. The reverse surface 29b is the surface of the reverse layer 193 that faces the z2 side in the thickness direction z, and faces the support substrate 3.

The obverse layer 192 (the obverse surface 19a) of the bonding member 19 is solid-phase bonded to the reverse surface electrode 15 of the first semiconductor element 10A (the second semiconductor element 10B). The reverse layer 193 (the reverse surface 19b) of the bonding member 19 is solid-phase bonded to the obverse surface 201 of the first conductive portion 2A (the second conductive portion 2B) of the conductive substrate 2. The obverse layer 192 (the obverse surface 29a) of the bonding member 29 is solid-phase bonded to the reverse surface 202 of the first conductive portion 2A (the second conductive portion 2B) of the conductive substrate 2. The reverse layer 193 (the reverse surface 29b) of the bonding member 29 is solid-phase bonded to the second metal layer 33 (the support surface 301) of the support substrate 3. The support substrate 3, the bonding member 29, the conductive substrate 2, the bonding member 19, and the first semiconductor element 10A (the second second semiconductor element 10B) are placed in this order in the thickness direction z and transported to a pressurizing device for performing solid-phase bonding, where solid-phase bonding of these components is performed in a single pressurization process.

FIG. 17 is an image of the bonding area between the bonding member 29 and the support substrate 3 taken using a scanning electron microscope (SEM). The image shows the state after 100 cycles of temperature cycling testing. As shown in FIG. 17, the bonding interface between the reverse layer 193 (the reverse surface 29b) of the bonding member 29 and the second metal layer 33 (the support surface 301) of the support substrate 3 exhibits a properly bonded state.

Each of the first terminal 41, the second terminal 42, the third terminals 43, and the fourth terminal 44 is provided by a plate made of a metal. The constituent material of the metal plate is, for example, Cu or a Cu alloy. In the example shown in FIGS. 1 to 5, 7 and 8, the semiconductor device A1 has one each of the first terminal 41, the second terminal 42 and the fourth terminal 44, and two third terminals 43.

The DC voltage to be converted is inputted to the first terminal 41, the second terminal 42, and the fourth terminal 44. The fourth terminal 44 is a positive electrode (P terminal), and each of the first terminal 41 and the second terminal 42 is a negative electrode (N terminal). The AC voltage converted by the first semiconductor elements 10A and the second semiconductor elements 10B is outputted from the third terminals 43. Each of the first terminal 41, the second terminal 42, the third terminals 43 and the fourth terminal 44 includes a portion covered with the sealing resin 8 and a portion exposed from the sealing resin 8.

As shown in FIG. 10, the fourth terminal 44 is formed integrally with the second conductive portion 2B. Unlike this configuration, the fourth terminal 44 may be provided separately from the second conductive portion 2B and conductively bonded to the second conductive portion 2B. As shown in FIG. 7 in particular, the fourth terminal 44 is located on the x2 side in the first direction x with respect to the second semiconductor elements 10B and the second conductive portion 2B (the conductive substrate 2). The fourth terminal 44 is electrically connected to the second conductive portion 2B and also electrically connected to the reverse surface electrode 15 (the drain electrode) of each second semiconductor element 10B via the second conductive portion 2B.

As shown in FIG. 7, the first terminal 41 and the second terminal 42 are spaced apart from the second conductive portion 2B. As shown in FIGS. 5 and 6, the first conductive member 5 is bonded to the first terminal 41 and the second terminal 42. As shown in FIGS. 5 and 7 in particular, the first terminal 41 and the second terminal 42 are located on the x2 side in the first direction x with respect to the second semiconductor elements 10B and the second conductive portion 2B (the conductive substrate 2). The first terminal 41 and the second terminal 42 are electrically connected to the first conductive member 5 and also electrically connected to the second obverse electrode 12 (the source electrode) of each first semiconductor element 10A via the first conductive member 5. As shown in FIGS. 1 to 5 and 8 in particular, in the semiconductor device A1, the first terminal 41, the second terminal 42 and the fourth terminal 44 protrude from the sealing resin 8 to the x2 side in the first direction x. The first terminal 41, the second terminal 42, and the fourth terminal 44 are spaced apart from each other. The first terminal 41 and the second terminal 42 are located opposite to each other across the fourth terminal 44 in the second direction y. The first terminal 41 is located on the y2 side in the second direction y of the fourth terminal 44, and the second terminal 42 is located on the y1 side in the second direction y of the fourth terminal 44. The first terminal 41, the second terminal 42, and the fourth terminal 44 overlap with each other as viewed in the second direction y.

As understood from FIGS. 7 and 9, the two third terminals 43 are integrally formed with the first conductive portion 2A. Unlike this configuration, the third terminals 43 may be provided separately from the first conductive portion 2A and conductively bonded to the first conductive portion 2A. As shown in FIG. 7 in particular, the two third terminals 43 are located on the x1 side in the first direction x with respect to the first semiconductor elements 10A and the first conductive portion 2A (the conductive substrate 2). Each third terminal 43 is electrically connected to the first conductive portion 2A and also electrically connected to the reverse surface electrode 15 (the drain electrode) of each first semiconductor element 10A via the first conductive portion 2A. The number of third terminals 43 is not limited to two, and may be one, or three or more. When only one third terminal 43 is provided, the third terminal 43 is preferably connected to the middle part in the second direction y of the first conductive portion 2A.

The control terminals 45 are pin-shaped terminals for controlling the first semiconductor elements 10A and the second semiconductor elements 10B. The control terminals 45 include a plurality of first control terminals 46A to 46D and a plurality of second control terminals 47A to 47E. The first control terminals 46A to 46D are used to control the first semiconductor elements 10A, for example. The second control terminals 47A to 47E are used to control the second semiconductor elements 10B, for example.

The first control terminals 46A to 46D are spaced apart from each other in the second direction y. As shown in FIGS. 7 and 10 in particular, the first control terminals 46A to 46D are supported on the first conductive portion 2A via the control terminal support 48 (the first support portion 48A, described later). As shown in FIGS. 5 and 7, the first control terminals 46A to 46D are located between the first semiconductor elements 10A and the two third terminals 43 in the first direction x.

The first control terminal 46A is a terminal (a gate terminal) for inputting a drive signal for the first semiconductor elements 10A. A drive signal for driving the first semiconductor elements 10A is inputted (e.g., a gate voltage is applied) to the first control terminal 46A.

The first control terminal 46B is a terminal (a source sense terminal) for detecting a source signal of the first semiconductor elements 10A. The voltage applied to the second obverse surface electrode 12 (the source electrode) of each first semiconductor element 10A (the voltage corresponding to the source current) is detected from the first control terminal 46B.

The first control terminal 46C and the first control terminal 46D are terminals electrically connected to a thermistor 17.

The second control terminals 47A to 47E are spaced apart from each other in the second direction y. As shown in FIGS. 7 and 10 in particular, the second control terminals 47A to 47E are supported on the second conductive portion 2B via the control terminal support 48 (the second support portion 48B, described later). As shown in FIGS. 5 and 7, the second control terminals 47A to 47E are located between the second semiconductor elements 10B and the first, the second and the fourth terminals 41, 42 and 44 in the first direction x.

The second control terminal 47A is a terminal (a gate terminal) for inputting a drive signal for the second semiconductor elements 10B. A drive signal for driving the second semiconductor elements 10B is inputted (e.g., a gate voltage is applied) to the second control terminal 47A. The second control terminal 47B is a terminal (a source sense terminal) for detecting a source signal of the second semiconductor elements 10B. The voltage applied to the second obverse surface electrode 12 (the source electrode) of each second semiconductor element 10B (the voltage corresponding to the source current) is detected from the second control terminal 47B. The second control terminal 47C and the second control terminal 47D are terminals electrically connected to a thermistor 17. The second control terminal 47E is a terminal (a drain sense terminal) for detecting a drain signal of the second semiconductor elements 10B. The voltage applied to the reverse surface electrode 15 (the drain electrode) of each second semiconductor element 10B (the voltage corresponding to the drain current) is detected from the second control terminal 47E.

Each of the control terminals 45 (the first control terminals 46A to 46D and the second control terminals 47A to 47E) includes a holder 451 and a metal pin 452.

The holders 451 are made of an electrically conductive material. As shown in FIGS. 11 and 12, the holders 451 are bonded to the control terminal support 48 (the first metal layer 482, described later) via a conductive bonding material 459. The constituent material of the conductive bonding material 459 is not limited and may be solder, metal paste, or sintered metal, for example. Each holder 451 includes a cylindrical portion, an upper flange portion, and a lower flange portion. The upper flange portion is connected to the upper part of the cylindrical portion, and the lower flange portion is connected to the lower part of the cylindrical portion. A metal pin 452 is inserted in at least the upper flange portion and the cylindrical portion of each holder 451. The holder 451 is mostly covered with the sealing resin 8. In the illustrated example, only the upper end surface of each holder 451 is exposed from the sealing resin 8.

The metal pins 452 are bar-shaped members extending in the thickness direction z. The metal pins 452 are supported by being press-fitted into the holders 451. The metal pins 452 are electrically connected to the control terminal support 48 (the first metal layer 482, described later) at least via the holders 451. When the lower ends (the ends on the z2 side in the thickness direction z) of the metal pins 452 are in contact with the conductive bonding material 459 within the through-holes of the holders 451 as in the example shown in FIGS. 11 and 12, the metal pins 452 are electrically connected to the control terminal support 48 via the conductive bonding material 459. The length of the metal pin 452 in the thickness direction z is not limited to the example shown in the figure and can be selected as appropriate.

The control terminal support 48 supports the plurality of control terminals 45. The control terminal support 48 is interposed between the obverse surface 201 (the conductive substrate 2) and the control terminals 45 in the thickness direction z.

The control terminal support 48 includes a first support portion 48A and a second support portion 48B. The first support portion 48A is disposed on the first conductive portion 2A of the conductive substrate 2 and supports the first control terminals 46A to 46D of the control terminals 45. As shown in FIG. 11, the first support portion 48A is bonded to the first conductive portion 2A via a bonding material 49. The bonding material 49 may be electrically conductive or insulating, and may be solder, for example. The second support portion 48B is disposed on the second conductive portion 2B of the conductive substrate 2 and supports the second control terminals 47A to 47E of the control terminals 45. As shown in FIG. 12, the second support portion 48B is bonded to the second conductive portion 2B via a bonding material 49.

The control terminal support 48 (each of the first support portion 48A and the second support portion 48B) is provided by a DBC (Direct Bonded copper) substrate, for example. The control terminal support 48 includes an insulating layer 481, a first metal layer 482, and a second metal layer 483 laminated on top of each other.

The insulating layer 481 is made of a ceramic material, for example. The insulating layer 481 may be rectangular in plan view.

As shown in FIGS. 11 and 12 in particular, the first metal layer 482 is formed on the upper surface of the insulating layer 481. Each control terminal 45 stands on the first metal layer 482. The first metal layer 482 is Cu or a Cu alloy, for example. As shown in FIG. 7 in particular, the first metal layer 482 includes a first portion 482A, a second portion 482B, a third portion 482C, a fourth portion 482D, a fifth portion 482E, and a sixth portion 482F. The first portion 482A, the second portion 482B, the third portion 482C, the fourth portion 482D, the fifth portion 482E, and the sixth portion 482F are spaced apart and insulated from each other.

The first portion 482A, to which a plurality of wires 71 are bonded, is electrically connected to the first obverse surface electrodes 11 (gate electrodes) of the first semiconductor elements 10A (the second semiconductor elements 10B) via the wires 71. The first portion 482A and the sixth portion 482F are connected via a plurality of wires 73. Thus, the sixth portion 482F is electrically connected to the first obverse surface electrodes 11 (gate electrodes) of the first semiconductor elements 10A (the second semiconductor elements 10B) via the wires 73 and the wires 71. As shown in FIG. 7, the first control terminal 46A is bonded to the sixth portion 482F of the first support portion 48A, and the second control terminal 47A is bonded to the sixth portion 482F of the second support portion 48B.

The second portion 482B, to which a plurality of wires 72 are bonded, is electrically connected to the second obverse surface electrodes 12 (source electrodes) of the first semiconductor elements 10A (the second semiconductor elements 10B) via the wires 72. As shown in FIG. 7, the first control terminal 46B is bonded to the second portion 482B of the first support portion 48A, and the second control terminal 47B is bonded to the second portion 482B of the second support portion 48B.

A thermistor 17 is bonded to the third portion 482C and the fourth portion 482D. As shown in Fig. [symbol] , the first control terminals 46C and 46D are bonded to the third portion 482C and the fourth portion 482D, respectively, of the first support portion 48A. The second control terminals 47C and 47D are bonded to the third portion 482C and the fourth portion 482D, respectively, of the second support portion 48B.

The fifth portion 482E of the first support portion 48A is not electrically connected to other components. The fifth portion 482E of the second support portion 48B, to which a wire 74 is bonded, is electrically connected to the second conductive portion 2B via the wire 74. As shown in FIG. 7, the second control terminal 47E is bonded to the fifth portion 482E of the second support portion 48B. Each of the wires 71 to 74 is, for example, a bonding wire. The constituent material of the wires 71 to 74 is not limited and includes one of Au (gold), Al or Cu, for example.

As shown in FIGS. 11 and 12 in particular, the second metal layer 483 is formed on the lower surface of the insulating layer 481. The second metal layer 483 is Cu or a Cu alloy, for example. As shown in FIG. 11, the second metal layer 483 of the first support portion 48A is bonded to the first conductive portion 2A via a bonding material 49. As shown in FIG. 12, the second metal layer 483 of the second support portion 48B is bonded to the second conductive portion 2B via a bonding material 49.

The first conductive member 5 and the second conductive member 6, together with the conductive substrate 2, form a path for the main circuit current switched by the first semiconductor elements 10A and the second semiconductor elements 10B. The first conductive member 5 and the second conductive member 6 are spaced apart from the obverse surface 201 (the conductive substrate 2) to the z1 side in the thickness direction z and overlap with the obverse surface 201 in plan view. In the present embodiment, each of the first conductive member 5 and the second conductive member 6 is provided by a plate made of a metal. The metal is Cu or a Cu alloy, for example. Specifically, each of the first conductive member 5 and the second conductive member 6 is a metal plate bent as appropriate.

The first conductive member 5 is connected to the second obverse surface electrode 12 (the source electrode) of each first semiconductor element 10A and the first and the second terminals 41 and 42 to electrically connect the second obverse surface electrode 12 of each first semiconductor element 10A and the first and the second terminals 41 and 42 to each other. The first conductive member 5 forms a path for the main circuit current switched by the first semiconductor elements 10A. The first conductive member 5 has a maximum dimension in the first direction x of 25 mm to 40 mm, for example, and a maximum dimension in the second direction y of 30 mm to 45 mm, for example. As shown in FIGS. 6 and 7, the first conductive member 5 includes a first wiring portion 51, a second wiring portion 52, a third wiring portion 53, a fourth wiring portion 54, and a fifth wiring portion 55.

The first wiring portion 51 has a first end 511, a second end 512, and a plurality of openings 513. The first end 511 is connected to the first terminal 41. The first end 511 and the first terminal 41 are bonded together with a conductive bonding material 59. The constituent material of the conductive bonding material 59 is not limited and may be solder, metal paste, or sintered metal, for example. The first wiring portion 51 as a whole has a band shape extending in the first direction x in plan view. The first wiring portion 51 overlaps with both the second conductive portion 2B and the first conductive portion 2A in plan view.

The second end 512 is spaced apart from the first end 511 in the first direction x. As shown in FIG. 6 in particular, the second end 512 is located on the x1 in the first direction x with respect to the first end 511.

Each of the openings 513 is a portion partially cut away in plan view. The openings 513 are spaced apart from each other in the first direction x. In the illustrated example, the first wiring portion 51 has three openings 513. The opening 513 on the x2 side in the first direction x and the opening 513 at the center in the first direction x are located at positions that overlap with the obverse surface 201 of the second conductive portion 2B (the conductive substrate 2) in plan view and do not overlap with the second semiconductor elements 10B in plan view. The opening 513 on the x1 side in the first direction x is located at a position that overlaps with the obverse surface 201 of the first conductive portion 2A (the conductive substrate 2) in plan view and does not overlap with the first semiconductor elements 10A in plan view. The openings 513 are provided at positions shifted to the y2 side in the second direction y of the second conductive portion 2B (the first conductive portion 2A) in plan view. In the present embodiment, the openings 513 are arcuate notches recessed to the y2 side in the second direction y from the y1-side edge in the first wiring portion 51. The shape in plan view of the openings 513 is not limited, and may be a notch as in the present embodiment, or a hole unlike the present embodiment.

The second wiring portion 52 has a third end 521, a fourth end 522, and a plurality of openings 523. The third end 521 is connected to the second terminal 42. The third end 521 and the second terminal 42 are bonded together with a conductive bonding material 59. The second wiring portion 52 as a whole has a band shape extending in the first direction x in plan view. The second wiring portion 52 is spaced apart from the first wiring portion 51 in the second direction y. The second wiring portion 52 is located on the y1 side in the second direction y with respect to the first wiring portion 51. The second wiring portion 52 overlaps with both the second conductive portion 2B and the first conductive portion 2A in plan view.

The fourth end 522 is spaced apart from the third end 521 in the first direction x. As shown in FIG. 6 in particular, the fourth end 522 is located on the x1 in the first direction x with respect to the third end 521.

Each of the openings 523 is a portion partially cut away in plan view. The openings 523 are spaced apart from each other in the first direction x. In the illustrated example, the second wiring portion 52 has three openings 523. The opening 523 on the x2 side in the first direction x and the opening 523 at the center in the first direction x are located at positions that overlap with the obverse surface 201 of the second conductive portion 2B (the conductive substrate 2) in plan view and do not overlap with the second semiconductor elements 20B in plan view. The opening 523 on the x1 side in the first direction x is located at a position that overlaps with the obverse surface 201 of the first conductive portion 2A (the conductive substrate 2) in plan view and does not overlap with the first semiconductor elements 10A in plan view. The openings 523 are provided at positions shifted to the y1 side in the second direction y of the second conductive portion 2B (the first conductive portion 2A) in plan view. In the present embodiment, the openings 523 are arcuate notches recessed to the y1 side in the second direction y from the y2-side edge in the second wiring portion 52. The shape in plan view of the openings 523 is not limited, and may be a notch as in the present embodiment, or a hole unlike the present embodiment.

The third wiring portion 53 is connected to both of the first wiring portion 51 (the second end 512) and the second wiring portion 52 (the fourth end 522). The third wiring portion 53 has a band shape extending in the second direction y in plan view. As understood from FIG. 6 in particular, the third wiring portion 53 overlaps with the first semiconductor elements 10A in plan view. As shown in FIG. 14, the third wiring portion 53 is connected to each of the first semiconductor elements 10A.

The third wiring portion 53 has a plurality of dented regions 531. As shown in FIG. 14 in particular, each of the dented regions 531 protrudes to the z2 side in the thickness direction z relative to other portions of the third wiring portion 53. Each of the dented regions 531 is connected to one of the first semiconductor elements 10A. Each dented region 531 of the third wiring portion 53 and the second obverse surface electrode 12 of a relevant first semiconductor element 10A are bonded to each other via a conductive bonding material 59. In the present embodiment, each dented region 531 is formed with an opening 531a. Preferably, each opening 531a is formed to overlap with the central portion of a first semiconductor element 10A in plan view. The openings 531a are, for example, through-holes formed in the dented regions 531 of the third wiring portion 53. The openings 531a are used, for example, to position the first conductive member 5 relative to the conductive substrate 2. The shape in plan view of openings 531a may be a perfect circle, or may be other shapes such as an ellipse or a rectangle.

The fourth wiring portion 54 is connected to both of the first wiring portion 51 and the second wiring portion 52. The fourth wiring portion 54 has a band shape extending in the second direction y in plan view. The fourth wiring portion 54 is connected to the first wiring portion 51 between the first end 511 and the second end 512 and connected to the second wiring portion 52 between the third end 521 and the fourth end 522. The fourth wiring portion 54 is spaced apart from the third wiring portion 53 in the first direction x. As shown in FIG. 6 in particular, the fourth wiring portion 54 is located on the x2 in the first direction x with respect to the third wiring portion 53. The fourth wiring portion 54 overlaps with the second semiconductor elements 10B in plan view.

The fourth wiring portion 54 has a plurality of elevated regions 541. As shown in FIG. 15 in particular, each of the elevated regions 541 protrudes to the z1 side in the thickness direction z relative to other portions of the fourth wiring portion 54. As shown in FIGS. 6 and 15 in particular, the elevated regions 541 and the second semiconductor elements 10B overlap with each other in plan view. As understood from FIG. 6 in particular, in the present embodiment, the positions in the second direction y of the dented regions 531 of the third wiring portion 53 are the same as those of the elevated regions 541.

The fifth wiring portion 55 is connected to both of the third wiring portion 53 and the fourth wiring portion 54. The fifth wiring portion 55 has a band shape extending in the first direction x in plan view. In the present embodiment, the first conductive member 5 includes a plurality of (three) fifth wiring portions 55. The fifth wiring portions 55 are located between the first wiring portion 51 and the second wiring portion 52 in the second direction y and spaced apart from each other in the second direction y. The fifth wiring portions 55 are disposed in parallel (or generally in parallel) with each other. The end on the x1 side in the first direction x of each fifth wiring portion 55 is connected between two dented regions 531 adjacent to each other in the second direction y of the third wiring portion 53. The end on the x2 side in the first direction x of each fifth wiring portion 55 is connected between two elevated regions 541 adjacent to each other in the second direction y of the fourth wiring portion 54.

The second conductive member 6 is connected to the second obverse surface electrode 12 (the source electrode) of each second semiconductor element 10B and the first conductive portion 2A to electrically connect the second obverse surface electrode 12 of each second semiconductor element 10B and the first conductive portion 2A to each other. The second conductive member 6 forms a path for the main circuit current switched by the second semiconductor elements 10B. As shown in FIGS. 6 and 7, the second conductive member 6 includes a main part 61, a plurality of first connecting ends 62, and a plurality of second connecting ends 63.

The main part 61 is located between the second semiconductor elements 10B and the first conductive portion 2A in the x direction and has a band shape extending in the second direction y in plan view. As shown in FIG. 13 in particular, the main part 61 is located on the z2 side in the thickness direction z with respect to the fifth wiring portion 55 of the first conductive member 5 and located closer to the obverse surface 201 (the conductive substrate 2) than are the fifth wiring portion 55. The main part 61 overlaps with the fifth wiring portions 55 in plan view. In the present embodiment, as shown in FIGS. 6, 7 and 10 in particular, the main part 61 is formed with a plurality of openings 611. Each opening 611 is a through-hole penetrating in the thickness direction z, for example. The openings 611 are aligned in the second direction y in a mutually spaced manner. The openings 611 do not overlap with the fifth wiring portion 55 in plan view. The openings 611 are formed to facilitate the flow of the resin material between the upper side (z1 side in the thickness direction z) and the lower side (z2 side in the thickness direction z) at or near the main part 61 (the second conductive member 6) during the injection of a flowable resin material to form the sealing resin 8. The configuration of the main part 61 (the second conductive member 6) is not limited to this configuration. For example, the openings 611 may not be formed.

The first connecting ends 62 and the second connecting ends 63 are connected to the main part 61 and disposed correspondingly to the second semiconductor elements 10B. As shown in FIGS. 10 and 15 in particular, each of the first connecting ends 62 is bonded to the second obverse surface electrode 12 of a relevant one of the second semiconductor elements 10B via a conductive bonding material 69, and each of the second connecting ends 63 is bonded to the first conductive portion 2A via a conductive bonding material 69. The constituent material of the conductive bonding material 69 is not limited and may be solder, metal paste, or sintered metal, for example. In the present embodiment, each of the first connecting ends 62 is formed with an opening 621. Preferably, each opening 621 is formed to overlap with the central portion of a second semiconductor element 10B in plan view. The openings 621 are through-hole penetrating in the thickness direction z, for example. The openings 621 are used, for example, to position the second conductive member 6 relative to the conductive substrate 2. The planar shape of the openings 621 may be a perfect circle or other shapes such as an oval, rectangle, or the like.

The sealing resin 8 covers the first semiconductor elements 10A, the second semiconductor elements 10B, the conductive substrate 2, the support substrate 3 (excluding the bottom surface 302), a part of each of the first terminal 41, the second terminal 42, the third terminals 43 and the fourth terminal 44, a part of each of the control terminals 45, the control terminal support 48, the first conductive member 5, the second conductive member 6, and the wires 71 to 74. The sealing resin 8 is made of black epoxy resin, for example. The sealing resin 8 is formed by molding, for example. The sealing resin 8 has dimensions of, for example, about 35 mm to 60 mm in the first direction x, about 35 mm to 50 mm in the second direction y, and about 4 mm to 15 mm in the thickness direction z. These dimensions are the size of the largest portion along each direction. In the present embodiment, the sealing resin 8 has a resin obverse surface 81, a resin reverse surface 82, and a plurality of resin side surfaces 831 to 834.

As shown in FIGS. 9 and 14 in particular, the resin obverse surface 81 and the resin reverse surface 82 are spaced apart from each other in the thickness direction z. The resin obverse surface 81 faces the z1 side in the thickness direction z. The control terminals 45 (the first control terminals 46A to 46D and the second control terminals 47A to 47E) protrude from the resin obverse surface 81. The resin reverse surface 82 faces the z2 side in the thickness direction z. As shown in FIG. 8, the resin reverse surface 82 has a frame shape surrounding the bottom surface 302 of the support substrate 3 (the first metal layer 32) as viewed in the thickness direction z. The bottom surface 302 of the support substrate 3 is exposed from the resin reverse surface 82 and may be flush with the resin reverse surface 82.

Each of the resin side surfaces 831 to 834 is connected to both of the the resin obverse surface 81 and the resin reverse surface 82 and sandwiched between these surfaces in the thickness direction z. As shown in FIG. 4 in particular, the resin side surface 831 and the resin side surface 832 are spaced apart from each other in the first direction x. The resin side surface 831 faces the x1 side in the first direction x, and the resin side surface 832 faces the x2 side in the first direction x. The two third terminals 43 protrude from the resin side surface 831, and the first terminal 41, the second terminal 42 and the fourth terminal 44 protrude from the resin side surface 832. As shown in FIG. 4 in particular, the resin side surface 833 and the resin side surface 834 are spaced apart from each other in the second direction y. The resin side surface 833 faces the y1 side in the second direction y, and the resin side surface 834 faces the y2 side in the second direction y.

As shown in FIG. 4, the resin side surface 832 is formed with a plurality of recesses 832a. Each recess 832a is a portion recessed in the first direction x in plan view. One of the recesses 832a is formed between the first terminal 41 and the fourth terminal 44 in plan view, and another one of the recesses 832a is formed between the second terminal 42 and the fourth terminal 44 in plan view. The recesses 832a are provided to increase the creepage distance between the first terminal 41 and the fourth terminal 44 along the resin side surface 832 and the creepage distance between the second terminal 42 and the fourth terminal 44 along the resin side surface 832.

As shown in FIGS. 9 and 10 in particular, the sealing resin 8 has a plurality of protrusions 851 and resin void portions 86.

The protrusions 85 protrude from the resin obverse surface 81 in the thickness direction z. In plan view, the protrusions 85 are disposed at four corners of the sealing resin 8. Each protrusion 851 has a protrusion end surface 85a at its extremity (the end on the z1 side in the thickness direction z). The protrusion end surfaces 85a of the protrusions 85 are parallel (or generally parallel) with the resin obverse surface 81 and located on the same plane (x-y plane). Each protrusion 85 may have the shape of a hollow conical frustum with a bottom, for example. The protrusions 85 are used as spacers when the semiconductor device A1 is mounted on a control circuit board or the like of a device configured to use the power produced by the semiconductor device A1. Each protrusion 85 has a recess 85b and an inner wall surface 851c formed around the recess 85b. The shape of each protrusion 85 may be columnar, and preferably cylindrical. Preferably, the shape of the recess 85b is cylindrical, and the inner wall surface 851c is a single perfect circle in plan view.

The semiconductor device A1 may be mechanically fixed to a control circuit board or the like by screwing, for example. In such a case, female threads can be formed on the inner wall surfaces 85c of the recesses 85b of the protrusions 85. Insert nuts may be embedded in the recesses 85b of the protrusions 85.

As shown in FIG. 9, the resin void portions 86 extend from the resin obverse surface 81 to the obverse surface 201 of the conductive substrate 2 in the thickness direction z. The resin void portion 86 is tapered, with its sectional area decreasing as proceeding from the resin obverse surface 81 toward the obverse surface 201 (toward the z2 side in the thickness direction z). The resin void portions 86 are formed during the molding of the sealing resin 8 and the area where the sealing resin 8 is not formed during the molding process.

Though illustration is omitted, the resin void portions 86 are formed, for example, because the flowable resin material could not flow into these areas as a result of these areas being occupied by pressing members during the molding process of the sealing resin 8. Such pressing members are used to apply pressing force to the obverse surface 201 of the conductive substrate 2 during the molding process and inserted into the openings 513 and the openings 523 of the first conductive member 5. In this way, the conductive substrate 2 can be held by the pressing members without interference with the first conductive member 5, which eliminates or reduces the warpage of the support substrate 3, to which the conductive substrate 2 is bonded.

In the present embodiment, the semiconductor device A1 includes resin fill portions 88 as shown in FIG. 9 in particular. The resin fill portions 88 are loaded into the resin void portions 86 to fill the resin void portions 86. The resin fill portions 88 may be made of epoxy resin as with the sealing resin 8, but may be made of a material different from the sealing resin 8.

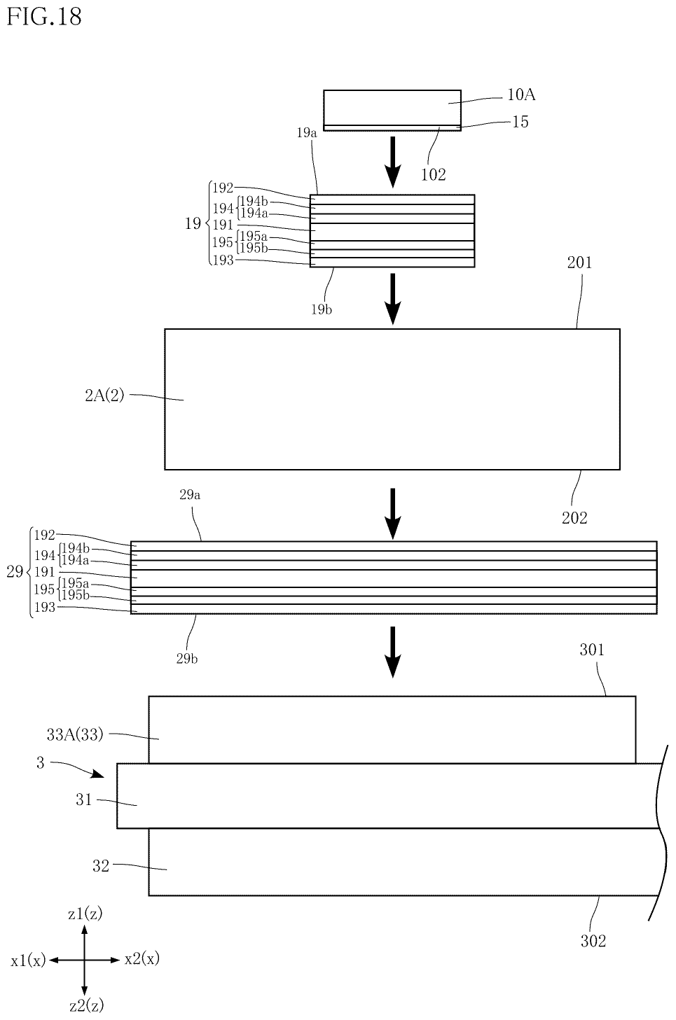

Next, an example of a method for bonding the support substrate 3, the conductive substrate 2, the first semiconductor elements 10A, and the second semiconductor elements 10B in a manufacturing method of the semiconductor device A1 will be described with reference to FIG. 18. FIG. 18 is a schematic front view corresponding to FIG. 16, showing a step of a method for manufacturing the semiconductor device A1.

First, the bonding members 29 are placed on the support substrate 3 as shown in FIG. 18. Specifically, each bonding member 29 is placed with the reverse surface 29b facing the support surface 301 of the first portion 33A (the second portion 33B) of the second metal layer 33 of the support substrate 3. Next, the conductive substrate 2 is placed on the bonding members 29. The conductive substrate 2 is placed with the reverse surface 202 facing the obverse surfaces 29a of the bonding members 29. More specifically, the first conductive portion 2A is placed with the reverse surface 202 facing the obverse surface 29a of the bonding member 29 placed on the first portion 33A. The second conductive portion 2B is placed with the reverse surface 202 facing the obverse surface 29a of the bonding member 29 placed on the second portion 33B. Next, bonding members 19 are placed on the first conductive portion 2A and the second conductive portion 2B. Each bonding member 19 is placed with the reverse surface 19b facing the obverse surface 201 of the first conductive portion 2A or the second conductive portion 2B. Next, a first semiconductor element 10A or a second semiconductor element 10B is placed on the obverse surface 19a of each bonding member 19. Each first semiconductor element 10A is placed with the element reverse surface 102 facing the obverse surface 19a of one of the bonding members 19 placed on the first conductive portion 2A. Each second semiconductor element 10B is placed with the element reverse surface 102 facing the obverse surface 19a of one of the bonding members 19 placed on the second conductive portion 2B.

Next, the support substrate 3, the bonding members 29, the conductive substrate 2, the bonding members 19, the first semiconductor elements 10A, and the second semiconductor elements 10B are set in a pressurizing device as one unit. Then, the pressurizing device applies pressure and heat while applying vibration to cause the mutually facing surfaces of the above components to be brought into direct contact and solid-phase bonded. The pressurizing device is not limited to such a configuration, and may not apply heat or vibration; it can have any configurations capable of solid-phase bonding the mutually facing surfaces of the above components.

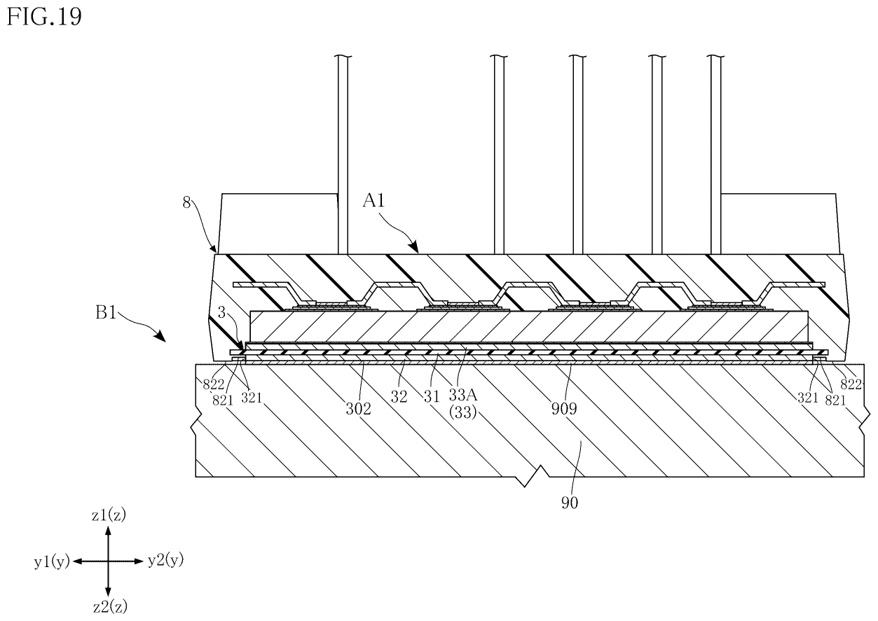

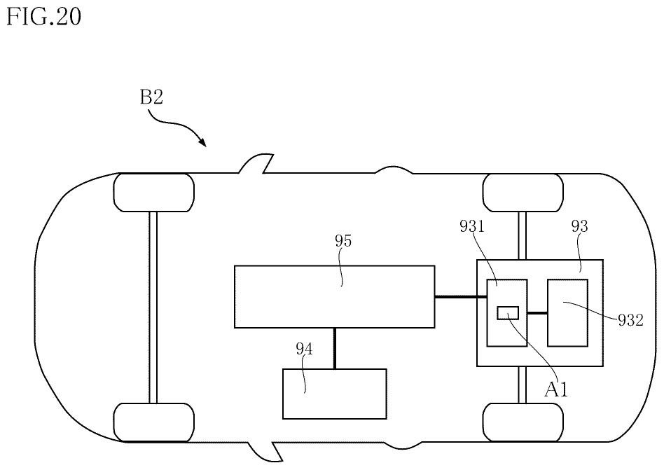

Next, examples of use of the semiconductor device A1 will be described based on FIGS. 19 and 20.

FIG. 19 shows a semiconductor device assembly B1 incorporating the semiconductor device A1. FIG. 19 is a partial sectional view of the semiconductor device assembly B1. The semiconductor device assembly B1 includes the semiconductor device A1 and a heat sink 90.

As shown in FIG. 19, the heat sink 90 is disposed to face the bottom surface 302 of the semiconductor device A1 (the support substrate 3). The heat sink 90 is bonded to the bottom surface 302 via a bonding layer 909. The heat sink 90 is a heat-dissipating member that dissipates the heat generated by the semiconductor device A1. The constituent material of the heat sink 90 is not limited and may be Al (aluminum), Cu (copper) or an alloy of these, for example.

The bonding layer 909 bonds the upper surface (the surface facing the z1 side in the thickness direction z) of the heat sink 90 and the bottom surface 302 of the support substrate 3. The constituent material of the bonding layer 909 is not limited and may be sintered metal, for example. For example, the bonding layer 909 may be a layer of sintered silver (Ag). In such a case, the thickness (the dimension in the thickness direction z) of the bonding layer 909 is relatively small and may be 50 to 500 μm, for example.

FIG. 20 is a schematic view of a vehicle B2 in which the semiconductor device A1 is mounted. The vehicle B2 is, for example, an electric vehicle (EV).

As shown in FIG. 20, the vehicle B2 includes an on-board charger 94, a storage battery 95, and a drive system 93. The on-board charger 94 receives electric power wirelessly from a power supply facility (not shown) installed outdoors. Alternatively, power supply from the power supply facility to the on-board charger 94 may be performed via a wired connection. The on-board charger 94 includes a step-up DC-DC converter. The voltage of the power supplied to the on-board charger 94 is increased by the converter and then supplied to the storage battery 95. The increased voltage is, for example, 600 V.

The drive system 93 drives the vehicle B2. The drive system 93 has an inverter 931 and a driving source 932. The semiconductor device A1 constitutes a part of the inverter 931. The power stored in the storage battery 95 is supplied to the inverter 931. The power supplied from the storage battery 95 to the inverter 931 is a direct current. Unlike the drive system 93 shown in FIG. 20, a step-up DC-DC converter may be additionally provided between the storage battery 95 and the inverter 931. The inverter 931 converts DC power into AC power. The inverter 931 including the semiconductor device A1 is electrically connected to the driving source 932. The driving source 932 has an AC motor and a transmission. When the AC power converted by the inverter 931 is supplied to the driving source 932, the AC motor rotates, and the rotation is transmitted to the transmission. The transmission appropriately reduces the rotation speed transmitted from the AC motor and rotates the drive shaft of the vehicle B2. Thus, the vehicle B2 is driven. When driving the vehicle B2, it is necessary to freely control the rotation speed of the AC motor based on the information such as the amount of movement of the accelerator pedal. The semiconductor device A1 in the inverter 931 is necessary to output the AC power with a frequency corresponding to the required rotation speed of the AC motor.

Next, the effects of the semiconductor device A1 will be described.

According to the present embodiment, the bonding member 19 is interposed between the first semiconductor element 10A (the second semiconductor element 10B) and the conductive substrate 2 and solid-phase bonded to each of these. Thus, the first semiconductor element 10A (the second semiconductor element 10B) and the conductive substrate 2 are firmly bonded together without the application of significant heat. The bonding member 29 is interposed between the conductive substrate 2 and the support substrate 3 and solid-phase bonded to each of these. Thus, the conductive substrate 2 and the support substrate 3 are firmly bonded together without the application of significant heat.

According to the present embodiment, the obverse surface 201 and the reverse surface 202 of the conductive substrate 2 are not provided with a metal layer such as Ag (silver) plating. Also, the support surface 301 of the support substrate 3 is not provided with a metal layer such as Ag (silver) plating. Therefore, the present embodiment does not require the process of forming metal layers on the obverse surface 201 and the reverse surface 202 of the conductive substrate 2 and the process of forming a metal layer on the support surface 301 of the support substrate 3. Thus, the semiconductor device A1 can simplify the bonding process and reduce the cost for bonding.

The bonding members 19 and 29 are metal foils in the present embodiment, but the present disclosure is not limited to this. The bonding members 19 and 29 may be metal plates.

In the present embodiment, the bonding member 19 bonds the first semiconductor element 10A (the second semiconductor element 10B) and the conductive substrate 2, and the bonding member 29 bonds the conductive substrate 2 and the support substrate 3, but the present disclosure is not limited to this. In the semiconductor device A1, the first semiconductor element 10A (the second semiconductor element 10B) and the conductive substrate 2 may be bonded with solder, metal paste, or sintered metal, for example. In the semiconductor device A1, the conductive substrate 2 and the support substrate 3 may be bonded with solder, metal paste, or sintered metal, for example.

The control terminal support 48 is bonded to the conductive substrate 2 via the bonding material 49 (e.g., solder) in the present embodiment, but the present disclosure is not limited to this. As with the first semiconductor element 10A and the second semiconductor element 10B, the control terminal support 48 may be bonded to the conductive substrate 2 via the bonding member 19. In such a case, a metal layer such as Ag (silver) plating may not be provided on the second metal layer 483 of the control terminal support 48.

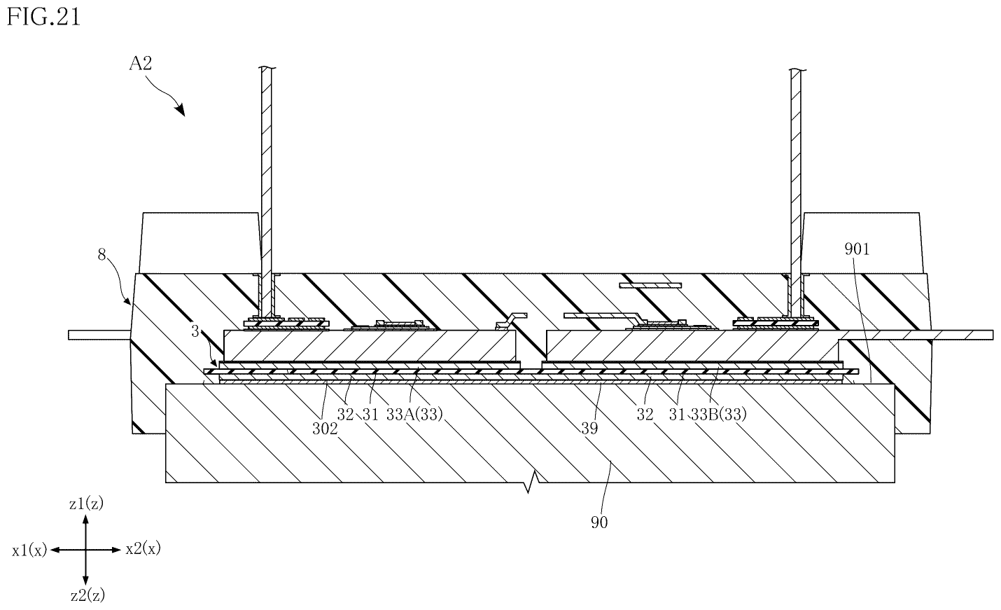

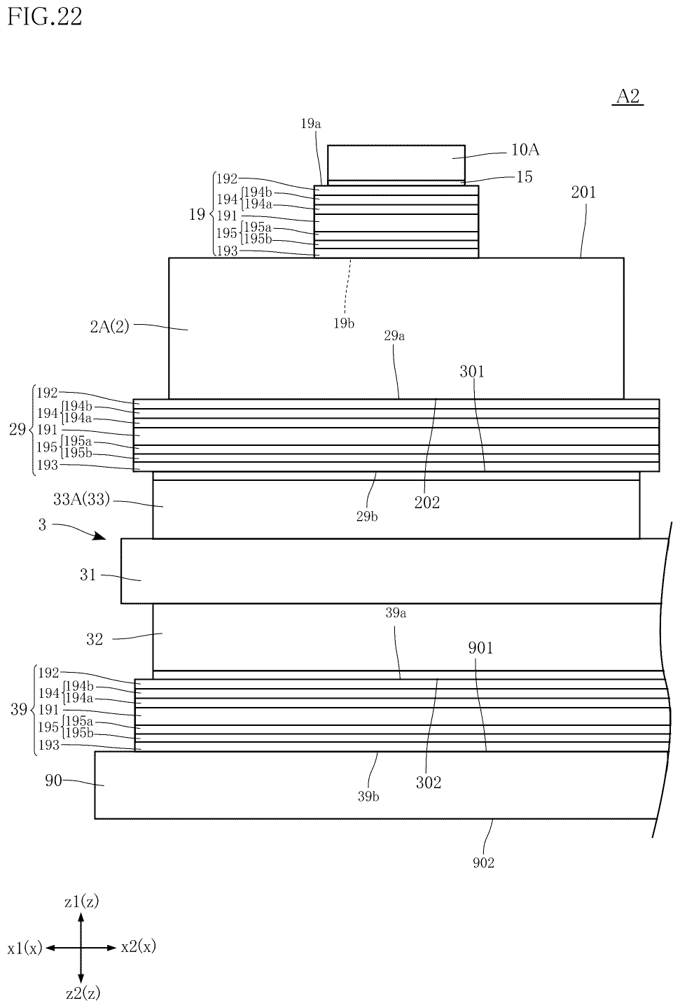

FIGS. 21 and 22 show another embodiment of the present disclosure. In these figures, the elements that are identical or similar to those of the above embodiment are denoted by the same reference signs as those used for the above embodiment, and the descriptions thereof are omitted. Various parts of each embodiment may be selectively used in any appropriate combination as long as it is technically compatible.

### Second Embodiment

FIGS. 21 and 22 show a semiconductor device A2 according to a second embodiment of the present disclosure. FIG. 21 is a sectional view of the semiconductor device A2 and corresponds to FIG. 10. FIG. 22 is a schematic front view corresponding to FIG. 16, showing the bonding structure of the semiconductor device A2. The semiconductor device A2 differs from the semiconductor device A1 in that the semiconductor device A2 includes a heat sink 90 and a part of the heat sink 90 is also covered with the sealing resin 8. The configurations and operations of other parts of the present embodiment are the same as those of the first embodiment. Various parts of the first embodiment and the variations may be optionally used in the present embodiment.

The semiconductor device A2 further includes a heat sink 90 and a bonding member 39.

The heat sink 90 is bonded to the support substrate 3 via the bonding member 39. The constituent material of the heat sink 90 is mainly composed of, for example, Cu (copper), and may be Cur or a Cu alloy. The constituent material of the heat sink 90 is not limited, may be mainly composed of other metals such as Al (aluminum).

The heat sink 90 has an obverse surface 901 and a reverse surface 902. The obverse surface 901 and the reverse surface 902 are spaced apart from each other in the thickness direction z. The obverse surface 901 faces the z1 side in the thickness direction z, and the reverse surface 902 faces the z2 side in the thickness direction z. The obverse surface 901 faces the support substrate 3 and is bonded to the support substrate 3 via the bonding member 39. The obverse surface 901 of the heat sink 90 is not provided with a metal layer such as Ag (silver) plating.

The bonding member 39 is interposed between the first metal layer 32 of the support substrate 3 and the heat sink 90 to bond the support substrate 3 and the heat sink 90. The bonding member 39 and the first metal layer 32 are solid-phase bonded, and the bonding member 39 and the heat sink 90 are solid-phase bonded. As shown in FIG. 22, the structure of the bonding member 39 is similar to that of the bonding members 19 and 29, and includes a body layer 191, an obverse layer 192, a reverse layer 193, and intermediate layers 194 and 195. The bonding member 39 has an obverse surface 39a and a reverse surface 39b. The obverse surface 39a and the reverse surface 39b are spaced apart from each other in the thickness direction z. The obverse surface 39a faces the z1 side in the thickness direction z, and the reverse surface 39b faces the z2 side in the thickness direction z. The obverse surface 39a is the surface of the obverse layer 192 that faces the z1 side in the thickness direction z, and faces the support substrate 3. The reverse surface 39b is the surface of the reverse layer 193 that faces the z2 side in the thickness direction z, and faces the heat sink 90. The obverse layer 192 (the obverse surface 39a) of the bonding member 39 is solid-phase bonded to the first metal layer 32 (the bottom surface 302) of the support substrate 3. The reverse layer 193 (the reverse surface 39b) of the bonding member 39 is solid-phase bonded to the heat sink 90 (the obverse surface 901).

In the present embodiment, solid-phase bonding of various components, including the bonding member 39 and the heat sink 90, is performed in a single pressurization process. That is, the heat sink 90, the bonding member 39, the support substrate 3, the bonding member 29, the conductive substrate 2, the bonding member 19, and the first semiconductor element 10A (the second semiconductor element 10B) are placed in this order in the thickness direction z and transported to a pressurizing device for performing solid-phase bonding, where solid-phase bonding of these components is performed at once.

In the present embodiment, as shown in FIG. 21, the sealing resin 8 covers a portion of the heat sink 90 and the bonding member 39 as well.

In the present embodiment again, the bonding member 19 is interposed between the first semiconductor element 10A (the second semiconductor element 10B) and the conductive substrate 2 and solid-phase bonded to each of these. Thus, the first semiconductor element 10A (the second semiconductor element 10B) and the conductive substrate 2 are firmly bonded together without the application of significant heat. The bonding member 29 is interposed between the conductive substrate 2 and the support substrate 3 and solid-phase bonded to each of these. Thus, the conductive substrate 2 and the support substrate 3 are firmly bonded together without the application of significant heat. Further, according to the present embodiment, the bonding member 39 is interposed between the support substrate 3 and the heat sink 90 and solid-phase bonded to each of these. Thus, the support substrate 3 and the heat sink 90 are firmly bonded together without the application of significant heat.

According to the present embodiment, the obverse surface 201 and the reverse surface 202 of the conductive substrate 2 are not provided with a metal layer such as Ag (silver) plating. Also, the support surface 301 and the bottom surface 302 of the support substrate 3 is not provided with a metal layer such as Ag (silver) plating. Further, the obverse surface 901 of the heat sink 90 is not provided with a metal layer such as Ag (silver) plating. Therefore, the present embodiment does not require the process of forming metal layers on the obverse surface 201 and the reverse surface 202 of the conductive substrate 2, the process of forming metal layers on the support surface 301 and the bottom surface 302 of the support substrate 3, and the process of forming a metal layer on the obverse surface 901 of the heat sink 90. Thus, the semiconductor device A2 can simplify the bonding process and reduce the cost for bonding.

The bonding structure and the bonding method according to the present disclosure is also applicable to a semiconductor device having a structure different from those of the first and second embodiments when a first member and a second member constituting the semiconductor device are solid-phase bonded. The bonding structure and the bonding method according to the present disclosure is also applicable to a package incorporating an electronic component other than a semiconductor element when the first member and the second member are solid-phase bonded. The bonding structure and the bonding method according to the present disclosure is also applicable to a device or the like other than a package incorporating a semiconductor element or an electronic component when the first member and the second member are solid-phase bonded.

The bonding structure, the semiconductor device, and the bonding method according to the present disclosure is not limited to the above-described embodiments. Various modifications in design may be made freely in the specific structure of each part of the bonding structure and the semiconductor device as well as the specific process in each step of the bonding method according to the present disclosure.

The present disclosure includes the embodiments described in the following clauses.

### Clause 1

A bonding structure comprising:
a first member including a first layer mainly composed of a first metal; and
a second member including a second layer mainly composed of a second metal different from the first metal, wherein
the first layer of the first member and the second layer of the second member are solid-phase bonded.

### Clause 2

The bonding structure according to clause 1, wherein the first metal is Cu, and the second metal is Ag.

### Clause 3

The bonding structure according to clause 1, wherein the first metal is Cu, and the second metal is Au.

### Clause 4

The bonding structure according to clause 1, wherein the first metal is Au, and the second metal is Ag.

### Clause 5

A semiconductor device (A1) comprising:
the bonding structure as set forth in any one of clauses 1 to 4; and
a semiconductor element (10A, 10B).

### Clause 6

The semiconductor device according to clause 5, comprising:
a conductive substrate (2) as the first member; and
a first bonding member (19) as the second member, wherein the semiconductor element is conductively bonded to the conductive substrate via the first bonding member.

### Clause 7

The semiconductor device according to clause 5, comprising a first bonding member (19) as the second member, wherein the semiconductor element is the first member.

### Clause 8

The semiconductor device according to clause 6 or 7, wherein the first bonding member includes an obverse layer (192) and a reverse layer (193) on opposite ends in a thickness direction (z), the obverse layer and the reverse layer containing Ag.

### Clause 9

The semiconductor device according to clause 8, wherein the first bonding member further includes a body layer (191) interposed between the obverse layer and the reverse layer in the thickness direction, the body layer containing Al.

### Clause 10

The semiconductor device according to any one of clauses 6 to 9, wherein the first bonding member is a metal foil.

### Clause 11

The semiconductor device according to clause 5, comprising:
a support substrate (3) as the first member; and
a second bonding member (29) as the second member, wherein the semiconductor element is mounted on the support substrate via the second bonding member.

### Clause 12

The semiconductor device according to clause 11, further comprising a conductive substrate (2) disposed opposite to the support substrate with respect to the second bonding member, the conductive substrate being solid-phase bonded to the second bonding member.

### Clause 13. (The second embodiment, FIGS. 21 and 22)

The semiconductor device according to clause 5, comprising:
a heat sink (90) as the first member; and
a third bonding member (39) as the second member, wherein heat generated by the semiconductor element is conducted to the heat sink via the third bonding member.

### Clause 13-1. (FIG. 20)

A vehicle comprising:
a driving source (932); and
the semiconductor device as set forth in any one of clauses 5 to 13, wherein the semiconductor device is electrically connected to the driving source.

### Clause 14. (FIG. 18)

A bonding method comprising:
preparing a first member including a first layer mainly composed of a first metal, and a second member including a second layer mainly composed of a second metal different from the first metal; and
solid-phase bonding the first layer of the first member and the second layer of the second member.

### Clause 15

The bonding method according to clause 14, wherein the second member includes:
an obverse layer and a reverse layer disposed on opposite ends in a thickness direction and containing Ag; and
a body layer interposed between the obverse layer and the reverse layer in the thickness direction and containing Al.

### REFERENCE NUMERALS

A1, A2: Semiconductor device 10A: First semiconductor element 10B: Second semiconductor element 101: Element obverse surface 102: Element reverse surface 11: First obverse surface electrode 12: Second obverse surface electrode 13: Third obverse surface electrode 15: Reverse surface electrode 17: Thermistor 19, 29, 39: Bonding member 191: Body layer 192: Obverse layer 193: Reverse layer 194: Intermediate layer 194a: Ni layer 194b: Cu layer 195: Intermediate layer 195a: Ni layer 195b: Cu layer 19a, 29a, 39a: Obverse surface 19b, 29b, 39b: Reverse surface 2: Conductive substrate 2A: First conductive portion 2B: Second conductive portion 201: Obverse surface 202: Reverse surface 3: Support substrate 301: Support surface 302: Bottom surface 31: Insulating layer 32: First metal layer 33: Second metal layer 33A: First portion 33B: Second portion 41: First terminal 42: Second terminal 43: Third terminal 44: Fourth terminal 45: Control terminal 451: Holder 452: Metal pin 459: Conductive bonding material 46A, 46B, 46C, 46D: First control terminal 47A, 47B, 47C, 47D, 47E: Second control terminal 48: Control terminal support 48A: First support portion 48B: Second support portion 481: Insulating layer 482: First metal layer 482A: First portion 482B: Second portion 482C: Third portion 482D: Fourth portion 482E: Fifth portion 482F: Sixth portion 483: Second metal layer 49: Bonding material 5: First conductive member 51: First wiring portion 511: First end 512: Second end 513: Opening 52: Second wiring portion 521: Third end 522: Fourth end 523: Opening 53: Third wiring portion 531: Dented region 531a: Opening 54: Fourth wiring portion 541: Elevated region 55: Fifth wiring portion 59: Conductive bonding material 6: Second conductive member 61: Main part 611: Opening 62: First connecting end 621: Opening 63: Second connecting end 69: Conductive bonding material 71, 72, 73, 74: Wire 8: Sealing resin 81: Resin obverse surface 82: Resin reverse surface 831, 832: Resin side surface 832a: Recess 833, 834: Resin side surface 85: Protrusion 85a: Protrusion end surface 85b: Recess 85c: Inner wall surface 86: Resin void portion 88: Resin fill portion 90: Heat sink 901: Obverse surface 902: Reverse surface 909: Bonding layer B1: Semiconductor device assembly B2: Vehicle 93: Drive system 931: Inverter 932: Driving source 94: On-board charger 95: Storage battery

1. A bonding structure comprising:
a first member including a first layer mainly composed of a first metal; and
a second member including a second layer mainly composed of a second metal different from the first metal, wherein
the first layer of the first member and the second layer of the second member are solid-phase bonded.

2. The bonding structure according to claim 1, wherein the first metal is Cu, and the second metal is Ag.

3. The bonding structure according to claim 1, wherein the first metal is Cu, and the second metal is Au.

4. The bonding structure according to claim 1, wherein the first metal is Au, and the second metal is Ag.

5. A semiconductor device comprising:
the bonding structure as set forth in claim 1; and
a semiconductor element.

6. The semiconductor device according to claim 5, wherein the first member comprises a conductive substrate, and the second member comprises a first bonding member,
the semiconductor element is conductively bonded to the conductive substrate via the first bonding member.

7. The semiconductor device according to claim 5, wherein the second member comprises a first bonding member, and the semiconductor element is the first member.

8. The semiconductor device according to claim 6, wherein the first bonding member includes an obverse layer and a reverse layer on opposite ends in a thickness direction, and the obverse layer and the reverse layer contain Ag.

9. The semiconductor device according to claim 8, wherein the first bonding member further includes a body layer interposed between the obverse layer and the reverse layer in the thickness direction, the body layer containing Al.

10. The semiconductor device according to claim 6, wherein the first bonding member is a metal foil.

11. The semiconductor device according to claim 5, wherein the first member comprises a support substrate, and the second member comprises a second bonding member,
the semiconductor element is mounted on the support substrate via the second bonding member.

12. The semiconductor device according to claim 11, further comprising a conductive substrate disposed opposite to the support substrate with respect to the second bonding member, and the conductive substrate is solid-phase bonded to the second bonding member.

13. The semiconductor device according to claim 5, wherein the first member comprises a heat sink, and the second member comprises a third bonding member,
heat generated by the semiconductor element is conducted to the heat sink via the third bonding member.

14. A bonding method comprising:
preparing a first member including a first layer mainly composed of a first metal, and a second member including a second layer mainly composed of a second metal different from the first metal; and
solid-phase bonding the first layer of the first member and the second layer of the second member.

15. The bonding method according to claim 14, wherein the second member includes:
an obverse layer and a reverse layer disposed on opposite ends in a thickness direction and containing Ag; and
a body layer interposed between the obverse layer and the reverse layer in the thickness direction and containing Al.
